(19) United States
(12) Patent Application Publication
(10) Pub. No.: US 2021/0032275 A1
(43) Pub. Date: Feb. 4, 2021

(54) CYCLIC GERMANIUM SILYLAMIDO PRECURSORS FOR GE-CONTAINING FILM DEPOSITIONS AND METHODS OF USING THE SAME

(71) Applicant: L'Air Liquide, Société Anonyme pour l'Etude et l'Exploitation des Procédés Georges Claude, Paris (FR)

(72) Inventors: Naohisa NAKAGAWA, Yokohama (JP); Jean-Marc GIRARD, Versailles (FR); Raphael ROCHAT, Yokohama (JP); Takio KIZU, Kawasaki (JP); Jonathan MA, Lyon (FR); Vitaly NESTEROV, Yokohama (JP)

(21) Appl. No.: 16/943,797

(22) Filed: Jul. 30, 2020

Related U.S. Application Data
(60) Provisional application No. 62/880,253, filed on Jul. 30, 2019.

(51) Int. Cl. C07F 7/30; C23C 16/455; C23C 16/40; C23C 16/34; C23C 16/42

(52) U.S. Cl. CPC C07F 7/30; C23C 16/45553; C23C 16/42; C23C 16/34; C23C 16/407

(57) ABSTRACT

Methods for forming a Ge-containing film on a substrate comprise the steps of introducing a vapor of a cyclic Ge(II) silylamido precursor into a reactor having the substrate disposed therein and depositing at least part of the cyclic Ge(II) silylamido precursor onto the substrate to form the Ge-containing film using a vapor deposition method. The cyclic Ge(II) silylamido precursor is [SiMe₃-(N—)—SiMe₂-(N—)—SiMe₃]Ge(II) or [tBu-(N—)—SiMe₂-(N—)-tBu]Ge(II).

### CROSS REFERENCE TO RELATED APPLICATIONS

This application claims the benefit of priority under 35 U.S.C. § 119 (a) and (b) to U.S. Provisional Patent Application No. 62/880,253, filed Jul. 30, 2019, the entire contents of which are incorporated herein by reference.

### TECHNICAL FIELD

Disclosed are cyclic germanium silylamido precursors for depositing a Ge-containing film and methods of synthesizing the same and methods of using the same. In particular, the disclosed are cyclic Ge(II) silylamido precursors for Ge-containing film depositions and methods of synthesizing the same and methods of using the same.

### BACKGROUND

In semiconductor applications, a Ge channel has been considered as a very promising booster for further improving the performance of 3D NAND, because Ge has much higher mobility for both hole and electron than those in Si. The Ge channel is expected to be a key layer in 3D NAND due to high mobility property. The Ge channel formation in 3D NAND structure is challenging, because of i) creation of pure Ge layer without Carbon incorporation; ii) conformal deposition below 650° C., and iii) refilling into high-aspect-ratio (HAR) trenches (>100/1). In these cases, Ge atomic layer deposition (ALD) and chemical vapor deposition (CVD) technologies may provide the solutions for high-conformal deposition into deep-narrow trenches.

Key requirements of Ge film deposition in 3D NAND structures are listed in Table 1.

TABLE 1

| | | |
|---|---|---|
| Film | Deposition mode | ALD/CVD, High A/R > 100:1 |
| specifi- | Film quality | Pure Ge or Ge-containing films, |
| cation | | No carbon contamination |

| | |
|---|---|
| Deposition conditions | Wafer temperature <650° C., |
| | with or without plasma |
| | enhancement |

To achieve a pure-Ge ALD process, proper design and choice of Ge precursor are necessary. Considering pure-Ge(0) formation by ALD, Ge precursors in lower valency state such as Ge(II) may be advantageous than higher valency state Ge(VI). However, Ge(II) compounds often suffer from lower stability than Ge(VI) compounds depending on the choice of ligands. Sterically-hindered large ligands on a Ge(II) center may make the molecule stable, but may be non-volatile. Therefore, in order to synthesize stable and volatile Ge(II) precursors, design of ligand structure is considered as one of the key steps.

Ge-containing films without Carbon incorporation, in particular silicon germanium oxide (SiGeO) films, are applied to waveguides in photonics (see for example US20020154878A1). For such applications the refractive index of the materials is a key property. The refractive index can be tuned by changing atomic compositions, for example, an increase in the Ge concentration in SiGeO films increases the refractive index of the film. The ability to tune the refractive index is very valuable for these applications.

Various efforts have been made to design cyclic metal silylamido precursors for depositions. However, a limited number of cyclic Ge(II) silylamido precursors have been made.

U.S. Pat. No. 5,603,988 to Shapiro et al. discloses a chemical vapor deposition method for forming on a substrate a material selected from the group consisting of titanium nitride silicide, tantalum nitride silicide and mixtures thereof, by exposing to the substrate a silylamido complex selected from the group consisting of titanium silylamido complex, tantalum silylamido complex and mixtures thereof, wherein said silylamido complex is in vapor form, and said substrate is at a temperature sufficient to cause cleavage of Si—N bonds of said silylamido complex along with retention of some silyl groups of said silylamido complex to form said material. The silylamido complex has the chemical formula M(N_{w}(SiR₃)ₓ(SiR₂)_{y})_{z}, or M[N_{w}(SiR₃)ₓ(SiR₂)_{y}]_{z}(X) wherein each w, z and v individually is an integer of 1-4; each x and y individually is an integer of 0-4, provided that at least one of x and y is at least 1; each X is NR₂ or a halogen; each R individually is alkyl, aryl, allyl or vinyl; and M=titanium or tantalum or mixtures thereof.

U.S. Pat. No. 9,219,232 to Hunks et al. discloses a method of depositing germanium on a substrate with a vapor of a germanium amidinate precursor under vapor deposition conditions. The germanium amidinate precursor includes Ge(II) or Ge(IV), and at least one amidinate ligand of the formula [RNCXNR]— wherein each R is independently selected from H, C₁-C₆ alkyl, C₃-C₁₀ cycloalkyl, C₆-C₁₃ aryl, and —Si(R′)₃ wherein each R′ is independently selected from C₁-C₆ alkyl, and X is selected from among H, C₁-C₆ alkyl, C₁-C₆ alkoxy, —NR₁R₂, and —C(R₃)₃, wherein each of R₁, R₂ and R₃ is independently selected from H, C₁-C₆ alkyl, C₃-C₁₀cycloalkyl, C₆-C₁₃ aryl, and —Si(R₄)₃ wherein each R₄ is independently selected from C₁-C₆ alkyl, and wherein non-amidinate ligand(s) are selected from alkyl, alkoxy, dialkylamino, hydrido, —Si(R₄)₃ and halogen groups.

U.S. Pat. No. 7,064,224B1 to Lei et al. discloses organometallic precursors and deposition processes for fabricating conformal metal containing films on substrates such as silicon, metal nitrides and other metal layers. The organometallic precursors are N,N′-alkyl-1,1-alkylsilylamino metal complexes represented by the formula:

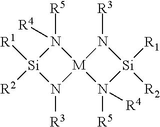

wherein M is a metal selected from the group consisting of Group VIIb, VIII, IX and X, and R¹⁻⁵ can be same or different selected from the group consisting of hydrogen, alkyl, alkoxy, fluoroalkyl, fluoroalkoxy, cycloaliphatic, and aryl. The organometallic complex of claim 1 wherein M is selected from the group consisting of cobalt, iron, nickel, manganese, ruthenium, zinc, copper, palladium, platinum, iridium, rhenium, and osmium.

U.S. Pat. No. 7,754,906 to Norman et al. discloses Ti, Ta, Hf, Zr and related metal siliconamides for ALD/CVD of metal-silicon nitrides, oxides or oxynitrides. Disclosed organometallic complexes include one having the following structure:

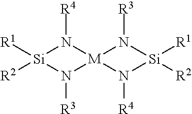

wherein M is a metal selected from Group 4 of the Periodic Table of the Elements and R¹⁻⁴ can be same or different selected from the group consisting of dialkylamide, difluoralkylamide, hydrogen, alkyl, alkoxy, fluoroalkyl and alkoxy, cycloaliphatic, and aryl with the additional provision that when R¹ and R² are dialkylamide, difluoralkylamide, alkoxy, fluoroalkyl and alkoxy, they can be connected to form a ring.

WO 2020/011637 to Schweinfurth et al. discloses processes for the generation of thin inorganic films on substrates, in particular ALD processes. It relates to a process for preparing metal- or semimetal-containing films comprising (a) depositing a metal- or semimetal-containing compound from the gaseous state onto a solid substrate and (b) bringing the solid substrate with the deposited metal- or semimetal-containing compound in contact with compound of general formula (II), (III), or (IV), wherein E is Ge or Sn, R is an alkyl group, an alkenyl group, an aryl group, or a silyl group, R′ are an alkyl group, an alkenyl group, an aryl group, or a silyl group, X is nothing, hydrogen, a halide, an alkyl group, an alkylene group, an aryl group, an alkoxy group, an aryl oxy group, an amino group, or a amidinate group, or an guanidinate group, L is an alkyl group, an alkenyl group, an aryl group, or a silyl group.

Veith et al. (“Cyclic Diazastannylenes, XVI Rings and Cages with Ge(II), Sn(II), and Pd(II), M. Veith*, and M. Grosser, Z. Naturforsch, 1982, 37b, 1375-1381) discloses a 4-membered-ring Ge(II) complex and its synthesis route as follows.

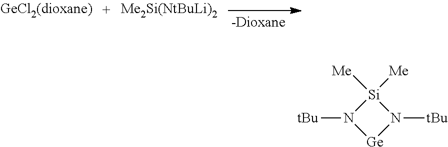

Veith et al. (“Stickstoffverbindungen von Elementen der dritten Hauptgruppe mit intra- und intermolekularen Donor-Akzeptor-Bindungen. I. Synthesen”, M. Veith et al, Chem. Ber., 1985, 118, 1600-1615) disclosed cyclic silylamido Al compounds and their synthesis routes as follows.

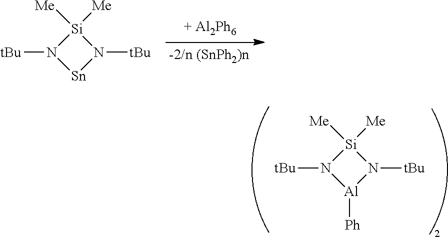

Rivard et al. (“Low-coordinate germylene and stannylene heterocycles featuring sterially tunable bis(amido)silyl ligands”, E. Rivard et al., Inorg. Chem, 2010, 49, 9709-9717) discloses 4-membered-ring Ge and Sn complexes and their synthesis routes as follows.

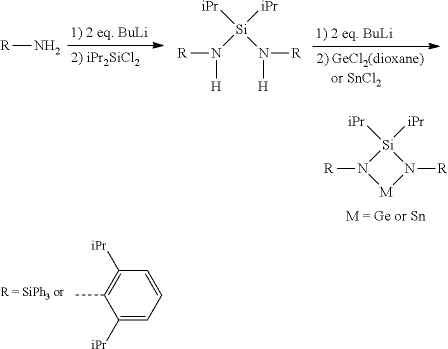

Ge(II)-[NSiAr₃]₂—[SiR₂]₂ and Sn(II) compounds are disclosed by Rivard et al. (“Expanding the steric coverage offered by bis(amidosilyl) chelates: Isolation of low-coordinate N-heterocyclic germylene complexes”, E. Rivard et al., Inorg. Chem, 2012, 51, 5471-5480).

Ge(IV)-[NSiMe₃]₂-SiMe₂ compounds are disclosed by Liewald et al. (“Silylamides of group IVa and IVb elements with spirobicycloheptane structure”, G. R. Liewald et al., J. Organomet. Chem, 1983, 259, 145-156).

Klingebiel et al. (“Diamino-di-tert-butylsilane als Bausteine cyclischer (SiN)2-, (SiNBN)2, (SiN2Sn)— und spirocyclischer (SiN2)₂Si—, (SiN2Sn)2S-Verbindungen”, U. Klingebiel et al., Z. Anorg. Allg. Chem., 1997, 623, 1264-1268) discloses

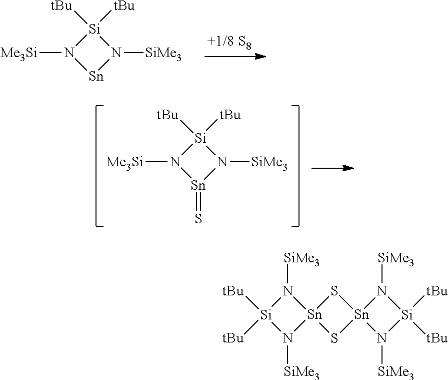

Kang et al. (“Syntheses, structural characterizations, and metathesis studies of new dimeric group 14 metal complexes derived from silacycloalkyl diamine”, So. O. Kang et al., Organometallics, 2002, 21, 5358-5365) discloses cyclic Sn(II) or Pb(II): [NtBu]₂-Si(cycloalkyl) ligand.

More Ti(IV) silyamido complexes, Zr(IV) silyamido complexes may be found in Synth. React. Inorg. Met. Chem. 1993, 23, 113-118. J. Organomet. Chem., 2014, 772-773, 27-33. Organometallics, 1997, 16, 5424-5436.

### SUMMARY

Disclosed are methods for forming a Ge-containing film on a substrate, comprising the steps of introducing a vapor of a cyclic Ge(II) silylamido precursor into a reactor having the substrate disposed therein and depositing at least part of the cyclic Ge(II) silylamido precursor onto the substrate to form the Ge-containing film using a vapor deposition method, wherein the cyclic Ge(II) silylamido precursor has a general formula:

Ge(II)(—N(R¹)—SiR₂—N(R²)—)

where R is selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group; R¹ and R² each are independently selected from a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, a C₁ to C₁₀ fluorinated alkyl group, or a silyl group SiR′₃ with each R′ being selected from a H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group.

The disclosed methods may include one or more of the following aspects:
the vapor deposition method being ALD with or without plasma enhancement;
the vapor deposition method being CVD with or without plasma enhancement;
the vapor deposition method being ALD, CVD or a combination thereof with or without plasma enhancement;
the method further comprising the step of delivering into the reactor a co-reactant;
the co-reactant being an oxidizing agent selected from O₂, O₃, H₂O, H₂O₂, NO, NO₂, alcohol, silanols, aminoalcohols, carboxylic acids, para-formaldehyde, or mixtures thereof, treated with or without plasma enhancement;
the co-reactant being a nitrogen-containing reducing agent selected from NH₃, N₂, H₂ or N₂H₂, amines, diamines, cyanides, di-imines, hydrazines, organic amines, pyrazoline, pyridine or mixtures thereof, treated with or without plasma enhancement;
the co-reactant being a silicon-containing reducing agent selected from (SiH₃)₃N, SiHₐX₄₋ₐ (X═Cl, Br, I; 0≤a≤4), Si₂H_{b}X_{c} (X═Cl, Br, I; 0≤b≤6; 0≤c≤6), Si₃H_{d}Xₑ (X═Cl, Br, I; 0≤d≤8; 0≤e≤8), hydridosilanes, chlorosilanes, chloropolysilanes, alkylsilanes, alkylaminosilanes, alkylamino disilanes, alkylaminotrisilanes, silylenes or mixtures thereof, treated with or without plasma enhancement;
the co-reactant being a Ge-containing reactant selected from GeCl₄, GeI₄, GeI₂, GeCl₂:L, GeI₂:L (L=dioxane and other neutral adduct) or mixtures thereof, treated with or without plasma enhancement;
the co-reactant being a compound of S/Se/Te selected from H₂X, R—X—R, R₃Si—X—SiR₃ (where X═S, Se, Te; R═C₁-C₁₀ alkyl) or mixtures thereof, treated with or without plasma enhancement;
the co-reactant being a compound of P/As/Sb selected from H₃X, RH₂X, R₂HX, R₃X (X═P/As/Sb; R=independently a halogen, a C₁-C₁₀ alkyl, a trialkyl silyl group), R₅X (R=halogen) or mixtures thereof, treated with or without plasma enhancement;
the co-reactant being a halide source selected from X₂, HX, SOX₂, SOX₄ (X═Cl, Br, I) or mixtures thereof, treated with or without plasma enhancement;
the cyclic Ge(II) silylamido precursors including 4-membered-ring Ge(II) precursors;
preferably R being Me and R¹ and R² each being —SiMe₃ or Butyl;
when R¹═R²=tBu, the disclosed cyclic Ge(II) silylamido precursor being a tBu-type compound, having a general formula:

[tBu-(N—)—SiR₂—(N—)-tBu]Ge(II)
where R is selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group;
the exemplary disclosed tBu-type compounds including [tBu-(N—)—SiMe₂-(N—)-tBu]Ge(II), [tBu-(N—)—SiEt₂-(N—)-tBu]Ge(II), [tBu-(N—)—SiPr₂—(N—)-tBu]Ge(II), [tBu-(N—)—SiBu₂-(N—)-tBu]Ge(II), [tBu-(N—)—SiMeEt-(N—)-tBu]Ge(II), [tBu-(N—)—SiMePr—(N—)-tBu]Ge(II), [tBu-(N—)—SiMeBu-(N—)-tBu]Ge(II), [tBu-(N—)—SiEtPr—(N—)-tBu]Ge(II), [tBu-(N—)—SiEtBu-(N—)-tBu]Ge(II), [tBu-(N—)—SiPrBu-(N—)-tBu]Ge(II), or the like;
when R¹═R²═SiMe₃, the disclosed cyclic Ge(II) silylamido precursor being a trimethylsilyl (TMS) substituted Ge(II) compound, having a general formula:

[SiMe₃-(N—)—SiR₂—(N—)—SiMe₃]Ge(II)
where R is independently selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group;
the exemplary disclosed TMS substituted Ge(II) compounds including [SiMe₃-(N—)—SiMe₂-(N—)—SiMe₃]Ge(II), [SiMe₃-(N—)—SiEt₂-(N—)—SiMe₃]Ge(II), [SiMe₃-(N—)—SiPr₂—(N—)—SiMe₃]Ge(II), [SiMe₃-(N—)—SiBu₂-(N—)—SiMe₃]Ge(II), [SiMe₃-(N—)—SiMeEt-(N—)—SiMe₃]Ge(II), [SiMe₃-(N—)—SiMePr—(N—)—SiMe₃]Ge(II), [SiMe₃-(N—)—SiMeBu-(N—)—SiMe₃]Ge(II), [SiMe₃-(N—)—SiEtPr—(N—)—SiMe₃]Ge(II), [SiMe₃-(N—)—SiEtBu-(N—)—SiMe₃]Ge(II), [SiMe₃-(N—)—SiPrBu-(N—)—SiMe₃]Ge(II), or the like;
the exemplary cyclic Ge(II) silylamido precursor including [SiEt₃-(N—)—SiMe₂-(N—)—SiEt₃]Ge(II), [SiPr₃—(N—)—SiMe₂-(N—)—SiPr₃]Ge(II), [SiBu₃-(N—)—SiMe₂-(N—)—SiBu₃]Ge(II), [SiEt₃-(N—)—SiEt₂-(N—)—SiEt₃]Ge(II), [SiPr₃—(N—)—SiEt₂-(N—)—SiPr₃]Ge(II), [SiBu₃-(N—)—SiEt₂-(N—)—SiBu₃]Ge(II), [SiEt₃-(N—)—SiPr₂—(N—)—SiEt₃]Ge(II), [SiPr₃—(N—)—SiPr₂—(N—)—SiPr₃]Ge(II), [SiBu₃-(N—)—SiPr₂—(N—)—SiBu₃]Ge(II), [SiEt₃-(N—)—SiBu₂-(N—)—SiEt₃]Ge(II), [SiPr₃—(N—)—SiBu₂-(N—)—SiPr₃]Ge(II), [SiBu₃-(N—)—SiBu₂-(N—)—SiBu₃]Ge(II), [SiEt₃-(N—)—SiMeEt-(N—)—SiEt₃]Ge(II), [SiPr₃—(N—)—SiMeEt-(N—)—SiPr₃]Ge(II), [SiBu₃-(N—)—SiMeEt-(N—)—SiBu₃]Ge(II), [SiEt₃-(N—)—SiMePr—(N—)—SiEt₃]Ge(II), [SiPr₃—(N—)—SiMePr—(N—)—SiPr₃]Ge(II), [SiBu₃-(N—)—SiMePr—(N—)—SiBu₃]Ge(II), [SiEt₃-(N—)—SiMeBu-(N—)—SiEt₃]Ge(II), [SiPr₃—(N—)—SiMeBu-(N—)—SiPr₃]Ge(II), [SiBu₃-(N—)—SiMeBu-(N—)—SiBu₃]Ge(II), [SiEt₃-(N—)—SiEtPr—(N—)—SiEt₃]Ge(II), [SiPr₃—(N—)—SiEtPr—(N—)—SiPr₃]Ge(II), [SiBu₃-(N—)—SiEtPr—(N—)—SiBu₃]Ge(II), [SiEt₃-(N—)—SiEtBu-(N—)—SiEt₃]Ge(II), [SiPr₃—(N—)—SiEtBu-(N—)—SiPr₃]Ge(II), [SiBu₃-(N—)—SiEtBu-(N—)—SiBu₃]Ge(II), [SiEt₃-(N—)—SiPrBu-(N—)—SiEt₃]Ge(II), [SiPr₃—(N—)—SiPrBu-(N—)—SiPr₃]Ge(II), [SiBu₃-(N—)—SiPrBu-(N—)—SiBu₃]Ge(II), or the like;
the cyclic Ge(II) silylamido precursor being [tBu-(N—)—SiMe₂-(N—)-tBu]Ge(II);
the cyclic Ge(II) silylamido precursor being [SiMe₃-(N—)—SiMe₂-(N—)—SiMe₃]Ge(II);
the Ge-containing film being a Ge (Ge(0)) film;
the Ge film being a chalcogenide material;
the Ge-containing film being a Ge oxide film, a Ge nitrogen film, or a GeSi film.
the Ge-containing film containing another element; and
the another element being P, Ga, As, B, Ta, Hf, Nb, Mg, Al, Sr, Y, Ba, Ca, As, Sb, Bi, Sn, Pb, Co, lanthanides (such as Er), or combinations thereof.

Also, disclosed is a composition comprising a cyclic Ge(II) silylamido precursor having a general formula:

Ge(II)(—N(R¹)—SiR₂—N(R²)—)

where R is selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group; R¹ and R² each are independently selected from a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, a C₁ to C₁₀ fluorinated alkyl group, or a silyl group SiR′₃ with each R′ being selected from a H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group.

The disclosed compositions include one or more of the following aspects:
the cyclic Ge(II) silylamido precursors including 4-membered-ring Ge(II) precursors;
preferably R being Me and R¹ and R² each being —SiMe₃ or Butyl;
when R¹═R²=tBu, the disclosed cyclic Ge(II) silylamido precursor being a tBu-type compound, having a general formula:

[tBu-(N—)—SiR₂—(N—)-tBu]Ge(II)
where R is selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group;
the exemplary disclosed tBu-type compounds including [tBu-(N—)—SiMe₂-(N—)-tBu]Ge(II), [tBu-(N—)—SiEt₂-(N—)-tBu]Ge(II), [tBu-(N—)—SiPr₂—(N—)-tBu]Ge(II), [tBu-(N—)—SiBu₂-(N—)-tBu]Ge(II), [tBu-(N—)—SiMeEt-(N—)-tBu]Ge(II), [tBu-(N—)—SiMePr—(N—)-tBu]Ge(II), [tBu-(N—)—SiMeBu-(N—)-tBu]Ge(II), [tBu-(N—)—SiEtPr—(N—)-tBu]Ge(II), [tBu-(N—)—SiEtBu-(N—)-tBu]Ge(II), [tBu-(N—)—SiPrBu-(N—)-tBu]Ge(II), or the like;
when R¹═R²═SiMe₃, the disclosed cyclic Ge(II) silylamido precursor being a TMS substituted Ge(II) compound, having a general formula:

[SiMe₃-(N—)—SiR₂—(N—)—SiMe₃]Ge(II)
where R is independently selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group;
the exemplary disclosed TMS substituted Ge(II) compounds including [SiMe₃-(N—)—SiMe₂-(N—)—SiMe₃]Ge(II), [SiMe₃-(N—)—SiEt₂-(N—)—SiMe₃]Ge(II), [SiMe₃-(N—)—SiPr₂—(N—)—SiMe₃]Ge(II), [SiMe₃-(N—)—SiBu₂-(N—)—SiMe₃]Ge(II), [SiMe₃-(N—)—SiMeEt-(N—)—SiMe₃]Ge(II), [SiMe₃-(N—)—SiMePr—(N—)—SiMe₃]Ge(II), [SiMe₃-(N—)—SiMeBu-(N—)—SiMe₃]Ge(II), [SiMe₃-(N—)—SiEtPr—(N—)—SiMe₃]Ge(II), [SiMe₃-(N—)—SiEtBu-(N—)—SiMe₃]Ge(II), [SiMe₃-(N—)—SiPrBu-(N—)—SiMe₃]Ge(II), or the like;
the exemplary cyclic Ge(II) silylamido precursor including [SiEt₃-(N—)—SiMe₂-(N—)—SiEt₃]Ge(II), [SiPr₃—(N—)—SiMe₂-(N—)—SiPr₃]Ge(II), [SiBu₃-(N—)—SiMe₂-(N—)—SiBu₃]Ge(II), [SiEt₃-(N—)—SiEt₂-(N—)—SiEt₃]Ge(II), [SiPr₃—(N—)—SiEt₂-(N—)—SiPr₃]Ge(II), [SiBu₃-(N—)—SiEt₂-(N—)—SiBu₃]Ge(II), [SiEt₃-(N—)—SiPr₂—(N—)—SiEt₃]Ge(II), [SiPr₃—(N—)—SiPr₂—(N—)—SiPr₃]Ge(II), [SiBu₃-(N—)—SiPr₂—(N—)—SiBu₃]Ge(II), [SiEt₃-(N—)—SiBu₂-(N—)—SiEt₃]Ge(II), [SiPr₃—(N—)—SiBu₂-(N—)—SiPr₃]Ge(II), [SiBu₃-(N—)—SiBu₂-(N—)—SiBu₃]Ge(II), [SiEt₃-(N—)—SiMeEt-(N—)—SiEt₃]Ge(II), [SiPr₃—(N—)—SiMeEt-(N—)—SiPr₃]Ge(II), [SiBu₃-(N—)—SiMeEt-(N—)—SiBu₃]Ge(II), [SiEt₃-(N—)—SiMePr—(N—)—SiEt₃]Ge(II), [SiPr₃—(N—)—SiMePr—(N—)—SiPr₃]Ge(II), [SiBu₃-(N—)—SiMePr—(N—)—SiBu₃]Ge(II), [SiEt₃-(N—)—SiMeBu-(N—)—SiEt₃]Ge(II), [SiPr₃—(N—)—SiMeBu-(N—)—SiPr₃]Ge(II), [SiBu₃-(N—)—SiMeBu-(N—)—SiBu₃]Ge(II), [SiEt₃-(N—)—SiEtPr—(N—)—SiEt₃]Ge(II), [SiPr₃—(N—)—SiEtPr—(N—)—SiPr₃]Ge(II), [SiBu₃-(N—)—SiEtPr—(N—)—SiBu₃]Ge(II), [SiEt₃-(N—)—SiEtBu-(N—)—SiEt₃]Ge(II), [SiPr₃—(N—)—SiEtBu-(N—)—SiPr₃]Ge(II), [SiBu₃-(N—)—SiEtBu-(N—)—SiBu₃]Ge(II), [SiEt₃-(N—)—SiPrBu-(N—)—SiEt₃]Ge(II), [SiPr₃—(N—)—SiPrBu-(N—)—SiPr₃]Ge(II), [SiBu₃-(N—)—SiPrBu-(N—)—SiBu₃]Ge(II), or the like;
the cyclic Ge(II) silylamido precursor being [SiMe₃-(N—)—SiMe₂-(N—)—SiMe₃]Ge(II);
the cyclic Ge(II) silylamido precursor having a purity ranging from approximately 93% w/w to approximately 100% w/w; and
the cyclic Ge(II) silylamido precursor having a purity ranging from approximately 99% w/w to approximately 99.999% w/w.

Also, disclosed is a film forming precursor having a general formula:

Ge(II)(—N(R¹)—SiR₂—N(R²)—)

where R is selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group; R¹ and R² each are independently selected from a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, a C₁ to C₁₀ fluorinated alkyl group, or a silyl group SiR′₃ with each R′ being selected from a H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group.

The disclosed film forming precursor include one or more of the following aspects:
the cyclic Ge(II) silylamido precursors including 4-membered-ring Ge(II) precursors;
preferably R being Me and R¹ and R² each being —SiMe₃ or Butyl;
when R¹═R²=tBu, the disclosed cyclic Ge(II) silylamido precursor being a tBu-type compound, having a general formula:

[tBu-(N—)—SiR₂—(N—)-tBu]Ge(II)
where R is selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group;
the exemplary disclosed tBu-type compounds including [tBu-(N—)—SiMe₂-(N—)-tBu]Ge(II), [tBu-(N—)—SiEt₂-(N—)-tBu]Ge(II), [tBu-(N—)—SiPr₂—(N—)-tBu]Ge(II), [tBu-(N—)—SiBu₂-(N—)-tBu]Ge(II), [tBu-(N—)—SiMeEt-(N—)-tBu]Ge(II), [tBu-(N—)—SiMePr—(N—)-tBu]Ge(II), [tBu-(N—)—SiMeBu-(N—)-tBu]Ge(II), [tBu-(N—)—SiEtPr—(N—)-tBu]Ge(II), [tBu-(N—)—SiEtBu-(N—)-tBu]Ge(II), [tBu-(N—)—SiPrBu-(N—)-tBu]Ge(II), or the like;
when R¹═R²═SiMe₃, the disclosed cyclic Ge(II) silylamido precursor being a TMS substituted Ge(II) compound, having a general formula:

[SiMe₃-(N—)—SiR₂—(N—)—SiMe₃]Ge(II)
where R is independently selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group;
the exemplary disclosed TMS substituted Ge(II) compounds including [SiMe₃-(N—)—SiMe₂-(N—)—SiMe₃]Ge(II), [SiMe₃-(N—)—SiEt₂-(N—)—SiMe₃]Ge(II), [SiMe₃-(N—)—SiPr₂—(N—)—SiMe₃]Ge(II), [SiMe₃-(N—)—SiBu₂-(N—)—SiMe₃]Ge(II), [SiMe₃-(N—)—SiMeEt-(N—)—SiMe₃]Ge(II), [SiMe₃-(N—)—SiMePr—(N—)—SiMe₃]Ge(II), [SiMe₃-(N—)—SiMeBu-(N—)—SiMe₃]Ge(II), [SiMe₃-(N—)—SiEtPr—(N—)—SiMe₃]Ge(II), [SiMe₃-(N—)—SiEtBu-(N—)—SiMe₃]Ge(II), [SiMe₃-(N—)—SiPrBu-(N—)—SiMe₃]Ge(II), or the like;
the exemplary cyclic Ge(II) silylamido precursor including [SiEt₃-(N—)—SiMe₂-(N—)—SiEt₃]Ge(II), [SiPr₃—(N—)—SiMe₂-(N—)—SiPr₃]Ge(II), [SiBu₃-(N—)—SiMe₂-(N—)—SiBu₃]Ge(II), [SiEt₃-(N—)—SiEt₂-(N—)—SiEt₃]Ge(II), [SiPr₃—(N—)—SiEt₂-(N—)—SiPr₃]Ge(II), [SiBu₃-(N—)—SiEt₂-(N—)—SiBu₃]Ge(II), [SiEt₃-(N—)—SiPr₂—(N—)—SiEt₃]Ge(II), [SiPr₃—(N—)—SiPr₂—(N—)—SiPr₃]Ge(II), [SiBu₃-(N—)—SiPr₂—(N—)—SiBu₃]Ge(II), [SiEt₃-(N—)—SiBu₂-(N—)—SiEt₃]Ge(II), [SiPr₃—(N—)—SiBu₂-(N—)—SiPr₃]Ge(II), [SiBu₃-(N—)—SiBu₂-(N—)—SiBu₃]Ge(II), [SiEt₃-(N—)—SiMeEt-(N—)—SiEt₃]Ge(II), [SiPr₃—(N—)—SiMeEt-(N—)—SiPr₃]Ge(II), [SiBu₃-(N—)—SiMeEt-(N—)—SiBu₃]Ge(II), [SiEt₃-(N—)—SiMePr—(N—)—SiEt₃]Ge(II), [SiPr₃—(N—)—SiMePr—(N—)—SiPr₃]Ge(II), [SiBu₃-(N—)—SiMePr—(N—)—SiBu₃]Ge(II), [SiEt₃-(N—)—SiMeBu-(N—)—SiEt₃]Ge(II), [SiPr₃—(N—)—SiMeBu-(N—)—SiPr₃]Ge(II), [SiBu₃-(N—)—SiMeBu-(N—)—SiBu₃]Ge(II), [SiEt₃-(N—)—SiEtPr—(N—)—SiEt₃]Ge(II), [SiPr₃—(N—)—SiEtPr—(N—)—SiPr₃]Ge(II), [SiBu₃-(N—)—SiEtPr—(N—)—SiBu₃]Ge(II), [SiEt₃-(N—)—SiEtBu-(N—)—SiEt₃]Ge(II), [SiPr₃—(N—)—SiEtBu-(N—)—SiPr₃]Ge(II), [SiBu₃-(N—)—SiEtBu-(N—)—SiBu₃]Ge(II), [SiEt₃-(N—)—SiPrBu-(N—)—SiEt₃]Ge(II), [SiPr₃—(N—)—SiPrBu-(N—)—SiPr₃]Ge(II), [SiBu₃-(N—)—SiPrBu-(N—)—SiBu₃]Ge(II), or the like;
the film forming precursor being [SiMe₃-(N—)—SiMe₂-(N—)—SiMe₃]Ge(II);
the film forming precursor having a purity ranging from approximately 93% w/w to approximately 100% w/w; and
the film forming precursor having a purity ranging from approximately 99% w/w to approximately 99.999% w/w.

### NOTATION AND NOMENCLATURE

The following detailed description and claims utilize a number of abbreviations, symbols, and terms, which are generally well known in the art, and include:

As used herein, the indefinite article “a” or “an” means one or more.

As used herein, “about” or “around” or “approximately” in the text or in a claim means ±10% of the value stated.

As used herein, “room temperature” in the text or in a claim means from approximately 20° C. to approximately 25° C.

The term “ambient temperature” refers to an environment temperature approximately 20° C. to approximately 25° C.

As used in the disclosed embodiments, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ(NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used in the disclosed embodiments, the term “hydrocarbyl group” refers to a functional group containing carbon and hydrogen; the term “alkyl group” refers to saturated functional groups containing exclusively carbon and hydrogen atoms. The hydrocarbyl group may be saturated or unsaturated. Either term refers to linear, branched, or cyclic groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used in the disclosed embodiments, the abbreviation “Me” refers to a methyl group; the abbreviation “Et” refers to an ethyl group; the abbreviation “Pr” refers to a propyl group.

Any and all ranges recited in the disclosed embodiments are inclusive of their endpoints (i.e., x=1 to 4 or x ranges from 1 to 4 includes x=1, x=4, and x=any number in between), irrespective of whether the term “inclusively” is used.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from a previous manufacturing step. For example, the wafers may include silicon layers (e.g., crystalline, amorphous, porous, etc.), Ge-containing layers (e.g., SiO₂, SiN, SiON, SiCOH, etc.), metal containing layers (e.g., copper, cobalt, ruthenium, tungsten, platinum, palladium, nickel, ruthenium, gold, etc.), an organic layer such as amorphous carbon, or a photoresist, or combinations thereof. Furthermore, the substrate may be planar or patterned. The substrate may include layers of oxides which are used as dielectric materials in MEMS, 3D NAND, MIM, DRAM, or FeRam device applications (for example, ZrO₂ based materials, HfO₂ based materials, TiO₂ based materials, rare earth oxide based materials, ternary oxide based materials, etc.) or nitride-based films (for example, TaN, TiN, NbN) that are used as electrodes. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates.

The term “wafer” or “patterned wafer” refers to a wafer having a stack of Ge-containing films on a substrate and a patterned hardmask layer on the stack of Ge-containing films formed for pattern etch. The term “wafer” or “patterned wafer” may also refers to a trench wafer having an aspect ratio.

Note that herein, the terms “film” and “layer” may be used interchangeably. It is understood that a film may correspond to, or related to a layer, and that the layer may refer to the film. Furthermore, one of ordinary skill in the art will recognize that the terms “film” or “layer” used herein refer to a thickness of some material laid on or spread over a surface and that the surface may range from as large as the entire wafer to as small as a trench or a line.

Note that herein, the terms “precursor” and “deposition compound” and “deposition gas” may be used interchangeably when the precursor is in a gaseous state at room temperature and ambient pressure. It is understood that a precursor may correspond to, or related to a deposition compound or deposition gas, and that the deposition compound or deposition gas may refer to the precursor.

As used herein, the abbreviation “NAND” refers to a “Negated AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

The standard abbreviations of the elements from the periodic table of elements are used herein. It should be understood that elements might be referred to by these abbreviation (e.g., Si refers to silicon, N refers to nitrogen, O refers to oxygen, C refers to carbon, H refers to hydrogen, F refers to fluorine, etc.).

The unique CAS registry numbers (i.e., “CAS”) assigned by the Chemical Abstract Service are provided to identify the specific molecules disclosed.

Ranges may be expressed herein as from about one particular value, and/or to about another particular value. When such a range is expressed, it is to be understood that another embodiment is from the one particular value and/or to the other particular value, along with all combinations within said range.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is vapour pressure (VP) results of [tBu-(N—)—SiMe₂-(N—)-tBu]Ge(II);

FIG. 2 is Thermogravimetric (TG) analysis results of [tBu-(N—)—SiMe₂-(N—)-tBu]Ge(II);

FIG. 3 is Differential scanning calorimetry (DSC) results of [tBu-(N—)—SiMe₂-(N—)-tBu]Ge(II) from room temperature to 250° C.;

FIG. 4 is DSC results of [tBu-(N—)—SiMe₂-(N—)-tBu]Ge(II) from room temperature to 500° C.;

FIG. 5a is X-ray photoelectron spectroscopy (XPS) results of pyrolysis of [tBu-(N—)—SiMe₂-(N—)-tBu]Ge(II) at 375° C.;

FIG. 5b is XPS results of pyrolysis of [tBu-(N—)—SiMe₂-(N—)-tBu]Ge(II) at 470° C. with four coupons and a reference coupon (not shown);

FIG. 5c is XPS results of pyrolysis of [tBu-(N—)—SiMe₂-(N—)-tBu]Ge(II) at 565° C. with four coupons and a reference coupon (not shown);

FIG. 6 is scanning electron microscope (SEM) results of deposited film using [tBu-(N—)—SiMe₂-(N—)-tBu]Ge(II) at 565° C.;

FIG. 7 is TG analysis results of [SiMe₃-(N—)—SiMe₂-(N—)—SiMe₃]Ge(II);

FIG. 8 is VP results of [SiMe₃-(N—)—SiMe₂-(N—)—SiMe₃]Ge(II);

FIG. 9 is DSC results of [SiMe₃-(N—)—SiMe₂-(N—)—SiMe₃]Ge(II) from room temperature to 500° C.;

FIG. 10a is XPS results of pyrolysis of [SiMe₃-(N—)—SiMe₂-(N—)—SiMe₃]Ge(II) at 565° C.;

FIG. 10b is XPS results of pyrolysis of [SiMe₃-(N—)—SiMe₂-(N—)—SiMe₃]Ge(II) at 615° C.;

FIG. 10c is XPS results of pyrolysis of [SiMe₃-(N—)—SiMe₂-(N—)—SiMe₃]Ge(I) at 665° C.;

FIG. 11 is scanning electron microscope (SEM) results of deposited film using [SiMe₃-(N—)—SiMe₂-(N—)—SiMe₃]Ge(II) at 665° C.;

FIG. 12 is the growth per cycle depending on the deposition temperature on ALD of [tBu-(N—)—SiMe₂-(N—)-tBu]Ge(II) with ozone;

FIG. 13 is the composition of ALD GeSi oxide film using [tBu-(N—)—SiMe₂-(N—)-tBu]Ge(II) with ozone;

FIG. 14a is the optical transmission of GeSi oxide film by[tBu-(N—)—SiMe₂-(N—)-tBu]Ge(II) with ozone;

FIG. 14b is the optical reflectance of GeSi oxide film by [tBu-(N—)—SiMe₂-(N—)-tBu]Ge(II) with ozone;

FIG. 15 is the growth per cycle depending on the deposition temperature on ALD of [SiMe₃-(N—)—SiMe₂-(N—)—SiMe₃]Ge(II) with ozone;

FIG. 16 is the composition of ALD GeSi oxide film using [SiMe₃-(N—)—SiMe₂-(N—)—SiMe₃]Ge(II) with ozone;

FIG. 17a is the optical transmission of GeSi oxide film by [SiMe₃-(N—)—SiMe₂-(N—)—SiMe₃]Ge(II) with ozone; and

FIG. 17b is the optical reflectance of GeSi oxide film by [SiMe₃-(N—)—SiMe₂-(N—)—SiMe₃]Ge(II) with ozone.

### DESCRIPTION OF PREFERRED EMBODIMENTS

Disclosed are Ge-containing film forming compositions comprising cyclic Ge(II) silylamido precursors, methods of synthesizing them and methods of using them to deposit a Ge-containing film. The disclosed cyclic Ge(II) silylamido precursors have a general formula:

Ge(II)(—N(R¹)—SiR₂—N(R²)—) (I)

where R is selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group; R¹ and R² each are independently selected from a C₁ to C₁₀ linear alkyl group, a C₃ to C₁₀ branched alkyl group, a C3 to C₁₀ cyclic alkyl group, a C₃ to C₁₀ alkenyl group, a C₄ to C₁₀ aryl group, a C₄ to C₁₀ heterocyclic group, a C₁ to C₁₀ fluorinated alkyl group, or a silyl group SiR′₃ with each R′ being selected from a H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group. Preferably R is Me and R¹ and R² each are —SiMe₃ or Butyl. The disclosed cyclic Ge(II) silylamido precursors includes 4-membered-ring Ge(II) precursors.

When R¹═R²=tBu in the formula (I), the disclosed cyclic Ge(II) silylamido precursor is a tBu-type compound, having a general formula:

[tBu-(N—)—SiR₂—(N—)-tBu]Ge(II) (II)

where R is selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group. The exemplary disclosed tBu-type compounds in the formula (II) may include [tBu-(N—)—SiMe₂-(N—)-tBu]Ge(II), [tBu-(N—)—SiEt₂-(N—)-tBu]Ge(II), [tBu-(N—)—SiPr₂—(N—)-tBu]Ge(II), [tBu-(N—)—SiBu₂-(N—)-tBu]Ge(II), [tBu-(N—)—SiMeEt-(N—)-tBu]Ge(II), [tBu-(N—)—SiMePr—(N—)-tBu]Ge(II), [tBu-(N—)—SiMeBu-(N—)-tBu]Ge(II), [tBu-(N—)—SiEtPr—(N—)-tBu]Ge(II), [tBu-(N—)—SiEtBu-(N—)-tBu]Ge(II), [tBu-(N—)—SiPrBu-(N—)-tBu]Ge(II), etc.

When R¹═R²═SiMe₃ in the formula (I), the disclosed cyclic Ge(II) silylamido precursor is a trimethylsilane (TMS) substituted Ge(II) compound, having a general formula:

[SiMe₃-(N—)—SiR₂—(N—)—SiMe₃]Ge(II) (III)

where R is independently selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group. The exemplary disclosed TMS substitute Ge(II) compounds in the formula (II) include [SiMe₃-(N—)—SiMe₂-(N—)—SiMe₃]Ge(II), [SiMe₃-(N—)—SiEt₂-(N—)—SiMe₃]Ge(I), [SiMe₃-(N—)—SiPr₂—(N—)—SiMe₃]Ge(II), [SiMe₃-(N—)—SiBu₂-(N—)—SiMe₃]Ge(II), [SiMe₃-(N—)—SiMeEt-(N—)—SiMe₃]Ge(II), [SiMe₃-(N—)—SiMePr—(N—)—SiMe₃]Ge(II), [SiMe₃-(N—)—SiMeBu-(N—)—SiMe₃]Ge(II), [SiMe₃-(N—)—SiEtPr—(N—)—SiMe₃]Ge(II), [SiMe₃-(N—)—SiEtBu-(N—)—SiMe₃]Ge(II), [SiMe₃-(N—)—SiPrBu-(N—)—SiMe₃]Ge(I), etc.

Here, —SiMe₃ group in the disclosed TMS substituted Ge(II) compounds in the formula (II) may be replaced with R′, forming

[SiR′—(N—)—SiR₂—(N—)—SiR′]Ge(II) (IV)

where R′ is selected from a H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group. The exemplary cyclic Ge(II) silylamido precursor in the formula (IV) may include [SiEt₃-(N—)—SiMe₂-(N—)—SiEt₃]Ge(II), [SiPr₃—(N—)—SiMe₂-(N—)—SiPr₃]Ge(II), [SiBu₃-(N—)—SiMe₂-(N—)—SiBu₃]Ge(II), [SiEt₃-(N—)—SiEt₂-(N—)—SiEt₃]Ge(II), [SiPr₃—(N—)—SiEt₂-(N—)—SiPr₃]Ge(II), [SiBu₃-(N—)—SiEt₂-(N—)—SiBu₃]Ge(II), [SiEt₃-(N—)—SiPr₂—(N—)—SiEt₃]Ge(II), [SiPr₃—(N—)—SiPr₂—(N—)—SiPr₃]Ge(II), [SiBu₃-(N—)—SiPr₂—(N—)—SiBu₃]Ge(II), [SiEt₃-(N—)—SiBu₂-(N—)—SiEt₃]Ge(II), [SiPr₃—(N—)—SiBu₂-(N—)—SiPr₃]Ge(II), [SiBu₃-(N—)—SiBu₂-(N—)—SiBu₃]Ge(II), [SiEt₃-(N—)—SiMeEt-(N—)—SiEt₃]Ge(II), [SiPr₃—(N—)—SiMeEt-(N—)—SiPr₃]Ge(II), [SiBu₃-(N—)—SiMeEt-(N—)—SiBu₃]Ge(II), [SiEt₃-(N—)—SiMePr—(N—)—SiEt₃]Ge(II), [SiPr₃—(N—)—SiMePr—(N—)—SiPr₃]Ge(II), [SiBu₃-(N—)—SiMePr—(N—)—SiBu₃]Ge(II), [SiEt₃-(N—)—SiMeBu-(N—)—SiEt₃]Ge(II), [SiPr₃—(N—)—SiMeBu-(N—)—SiPr₃]Ge(II), [SiBu₃-(N—)—SiMeBu-(N—)—SiBu₃]Ge(II), [SiEt₃-(N—)—SiEtPr—(N—)—SiEt₃]Ge(II), [SiPr₃—(N—)—SiEtPr—(N—)—SiPr₃]Ge(II), [SiBu₃-(N—)—SiEtPr—(N—)—SiBu₃]Ge(II), [SiEt₃-(N—)—SiEtBu-(N—)—SiEt₃]Ge(II), [SiPr₃—(N—)—SiEtBu-(N—)—SiPr₃]Ge(II), [SiBu₃-(N—)—SiEtBu-(N—)—SiBu₃]Ge(II), [SiEt₃-(N—)—SiPrBu-(N—)—SiEt₃]Ge(II), [SiPr₃—(N—)—SiPrBu-(N—)—SiPr₃]Ge(II), [SiBu₃-(N—)—SiPrBu-(N—)—SiBu₃]Ge(II), etc.

The disclosed cyclic Ge(II) silylamido precursor is [SiMe₃-(N—)—SiMe₂-(N—)—SiMe₃]Ge(II). The disclosed cyclic Ge(II) silylamido precursor is [tBu-(N—)—SiMe₂-(N—)-tBu]Ge(II). The boiling point of [tBu-(N—)—SiMe₂-(N—)-tBu]Ge(II) is 35° C. at 0.25 Torr. Here, Me on Si in both [SiMe₃-(N—)—SiMe₂-(N—)—SiMe₃]Ge(II) and [tBu-(N—)—SiMe₂-(N—)-tBu]Ge(II) may be replaced with R selected from H, a C₁ to C₁₀ linear alkyl group, a C3 to C1 branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group. See Table 2.

TABLE 2
Cyclic Ge(II) silylamido precursors

| Ge(II) compound | Structure | DSC | TG | VP |
|---|---|---|---|---|
| [tBu—(N—)—SiMe₂— (N—)—tBu]Ge(II) | 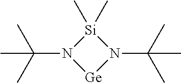 | decomp. btw. 250-500° C. | <0.3% residue @ 200° C. | 3.5 Torr @ 60° C. |
| [SiMe₃—(N—)—SiMe₂— (N—)—SiMe₃]Ge(II) | 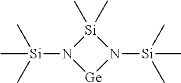 | exotherm from 380° C. | <0.5% residue @ 200° C. | 4.4 Torr @ 60° C. |

The disclosed methods for syntheses of the disclosed cyclic Ge(II) silylamido precursors include two steps as shown in examples that follow. The first step is a ligand synthesis step that synthesizes a silicon-containing intermediate, which may include several sub-steps to synthesize the silicon-containing intermediate. The second step is a precursor synthesis step that utilizes a Ge-containing compound to react with the silicon-containing intermediate to form the cyclic Ge(II) silylamido precursor. In one embodiment, GeCl₂(dioxane) may be used as a Ge-containing compound to react with the intermediate to produce the disclosed cyclic Ge(II) silylamido precursors.

The disclosed cyclic Ge(II) silylamido precursors may have high thermal stability and may be used for forming high mobility semiconductor layers, e.g. in logic devices or in 3D NAND as channel or in photovoltaic (PV) or in optical applications such as waveguides in photonics. The disclosed cyclic Ge(II) silylamido precursors may be used as a component in phase change memory, e.g., germanium-antimony-tellurium (GST) and the like, a component in ovonic threshold switching (OTS) selector, such as, GeSe, GeTe . . . , a seed layer in 3D NAND for Si recrystallization and an amorphisation element (Ge doped with metal oxide forms an amorphous state).

The disclosed cyclic Ge(II) silylamido precursors may be used for depositing a Ge-containing thin film in semiconductor applications, such as, Ge(0), GeO, GeN, GeSi, GeS, GeSe, GeTe, GeP, GeAs, GeSb films or the like.

The disclosed cyclic Ge(II) silylamido precursors may have the following features that are suitable for Ge film deposition.
Bond cleavage at Ge—N against Si—N
In the deposition processes (e.g., ALD or CVD), H₂ reduction is expected to occur at Ge—N bond that is weaker than Si—N bond.
Deposition (e.g., ALD or CVD) byproducts are expected to be volatile and thermally stable, and no film contamination is expected.
For instance, the byproduct of [tBu-(N—)—SiMe₂-(N—)-tBu]Ge(II) ALD is Me-BTBAS (BTBAS: Bis(t-butylamino)silane, [NH(CMe₃)]₂SiH₂,

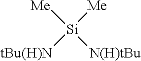

and the byproduct of [SiMe₃-(N—)—SiMe₂-(N—)—SiMe₃]Ge(II) ALD is Me-2TMSAS (2TMSAS: bis(trimethylsilylamino)silane, H₂Si(NH—SiMe₃)₂,

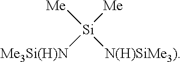

Both Me-BTBAS and Me-2TMSAS are thermally stable.
Synthetic perspective and high yielding.
Volatility—Molecular weight is not high, thus volatility is expected to be good.

To ensure process reliability, the disclosed Ge-containing film forming compositions may be purified by continuous or fractional batch distillation or sublimation prior to use to a purity ranging from approximately 93% by weight or w/w to approximately 100% w/w, preferably ranging from approximately 99% w/w to approximately 99.999% w/w, more preferably, ranging from approximately 99% w/w to approximately 100% w/w. One of ordinary skill in the art will recognize that the purity may be determined by H NMR or gas or liquid chromatography with mass spectrometry. The Ge-containing film forming compositions may contain any of the following impurities: ammonium salts; alkylamines, dialkylamines, alkylimines, THF, ether, pentane, cyclohexane, heptanes, toluene, halogenated metal compounds. Preferably, the total quantity of these impurities is below 0.1% w/w. The purified composition may be produced by recrystallization, sublimation, distillation, and/or passing the gas or liquid through a suitable adsorbent, such as 4 Å molecular sieves.

The disclosed Ge-containing film forming composition contains less than 5% v/v, preferably less than 1% v/v, more preferably less than 0.1% v/v, and even more preferably less than 0.01% v/v of any of its analogs or other reaction products. This embodiment may provide better process repeatability. This embodiment may be produced by distillation of the Ge-containing film forming composition.

The concentration of trace metals and metalloids in the purified Ge-containing film forming composition may each range independently from approximately 0 ppbw to approximately 100 ppbw, and more preferably from approximately 0 ppbw to approximately 10 ppbw. These metal or metalloid impurities include, but are not limited to, Aluminum(Al), Arsenic(As), Barium(Ba), Beryllium(Be), Bismuth(Bi), Cadmium(Cd), Calcium(Ca), Chromium(Cr), Cobalt(Co), Copper(Cu), Gallium(Ga), Hafnium(Hf), Zirconium(Zr), Indium(In), Iron(Fe), Lead(Pb), Lithium(Li), Magnesium(Mg), Manganese(Mn), Tungsten(W), Nickel(Ni), Potassium(K), Sodium(Na), Strontium(Sr), Thorium(Th), Tin(Sn), Titanium(Ti), Uranium(U), Vanadium(V) and Zinc(Zn). The concentration of X (where X═Cl, Br) in the purified Ge-containing film forming composition may range between approximately 0 ppmw and approximately 100 ppmw and more preferably between approximately 0 ppmw to approximately 10 ppmw.

Care should be taken to prevent exposure of the disclosed Ge-containing film forming compositions to water as this may result in decomposition of the cyclic Ge(II) silylamido precursors to a germanium oxide (GeOₓ, x is 1-4).

Also disclosed are methods of using the disclosed Ge-containing film forming compositions for vapor depositions. The disclosed methods provide for the use of the Ge-containing film forming compositions for deposition of Ge-containing films or a pure Ge (Ge(0)) layer. The disclosed methods may be useful in the manufacture of a channel layer.

The disclosed methods for forming a Ge-containing layer on a substrate include: placing a substrate in a reactor, delivering into the reactor a vapor of the disclosed Ge-containing film forming composition, and contacting the vapor with the substrate (and typically directing the vapor to the substrate) to form a Ge-containing layer on the surface of the substrate.

The methods may include forming a bimetal-containing layer on a substrate using the vapor deposition process and, more specifically, for deposition of a SiGe or SiGeO layer. The disclosed methods may be useful in the manufacture of a channel layer or for optical applications.

The disclosed Ge-containing film forming compositions may be used to deposit Ge-containing films using any deposition methods known to those of skill in the art. Examples of suitable deposition methods include chemical vapor deposition (CVD) or atomic layer deposition (ALD) with or without plasma enhancement. Exemplary CVD methods include thermal CVD, pulsed CVD (PCVD), low pressure CVD (LPCVD), subatmospheric CVD (SACVD) or atmospheric pressure CVD (APCVD), hot-wire CVD or hot filament CVD (also known as cat-CVD, in which a hot wire serves as an energy source for the deposition process), hot wall CVD, cold wall CVD, aerosol assisted CVD, direct liquid injection CVD, combustion CVD, hybrid physical-CVD, metalorganic CVD, rapid thermal CVD, photo-initiated CVD, laser CVD, radicals incorporated CVD, plasma enhanced CVD (PECVD) including but not limited to flowable PECVD, and combinations thereof. Exemplary ALD methods include thermal ALD, plasma enhanced ALD (PEALD), spatial isolation ALD, temporal ALD, selective or not ALD, hot-wire ALD (HWALD), radicals incorporated ALD, and combinations thereof. The deposition method is preferably ALD, PE-ALD, or spatial ALD in order to provide suitable step coverage and film thickness control.

The vapor of the Ge-containing film forming composition is generated and then introduced into a reaction chamber containing a substrate. The temperature and the pressure in the reaction chamber and the temperature of the substrate are held at conditions suitable for vapor deposition of at least part of the cyclic Ge(II) silylamido precursor onto the substrate. In other words, after introduction of the vaporized composition into the reaction chamber, conditions within the reaction chamber are adjusted such that at least part of the precursor is deposited onto the substrate to form the Ge-containing layer. One of ordinary skill in the art will recognize that “at least part of the precursor is deposited” means that some or all of the precursor reacts with or adheres to the substrate. Herein, a co-reactant may also be used to help in formation of the Ge-containing layer.

The reaction chamber may be any enclosure or chamber of a device in which deposition methods take place, such as, without limitation, a parallel-plate type reactor, a cold-wall type reactor, a hot-wall type reactor, a single-wafer reactor, a multi-wafer reactor, or other such types of deposition systems. All of these exemplary reaction chambers are capable of serving as an ALD or CVD reaction chamber. The reaction chamber may be maintained at a pressure ranging from about 0.5 mTorr to about 20 Torr for all ALD and subatmospheric CVD. Subatmospheric CVD and atmospheric CVD pressures may range up to 760 Torr (atmosphere). In addition, the temperature within the reaction chamber may range from about 20° C. to about 600° C. One of ordinary skill in the art will recognize that the temperature may be optimized through mere experimentation to achieve the desired result.

The temperature of the reactor may be controlled by either controlling the temperature of the substrate holder or controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 20° C. to approximately 600° C. When a plasma deposition process is utilized, the deposition temperature may range from approximately 20° C. to approximately 550° C. Alternatively, when a thermal process is performed, the deposition temperature may range from approximately 300° C. to approximately 600° C.

Alternatively, the substrate may be heated to a sufficient temperature to obtain the desired Ge-containing film at a sufficient growth rate and with desired physical state and composition. A non-limiting exemplary temperature range to which the substrate may be heated includes from room temperature to approximately 600° C. Preferably, the temperature of the substrate remains less than or equal to 500° C.

The reactor contains one or more substrates onto which the films will be deposited. A substrate is generally defined as the material on which a process is conducted. The substrates may be any suitable substrate used in semiconductor, photovoltaic, flat panel, or LCD-TFT device or photonics manufacturing. Examples of suitable substrates include wafers, such as silicon, silica, glass, or GaAs wafers. The wafer may have one or more layers of differing materials deposited on it from a previous manufacturing step. For example, the wafers may include silicon layers (crystalline, amorphous, porous, etc.), silicon oxide layers, silicon nitride layers, silicon oxy nitride layers, carbon doped silicon oxide (SiCOH) layers, or combinations thereof. Additionally, the wafers may include copper layers or noble metal layers (e.g. platinum, palladium, rhodium, or gold). The layers may include oxides which are used as dielectric materials in MIM, DRAM, or FeRam technologies (e.g., ZrO₂ based materials, HfO₂ based materials, TiO₂ based materials, rare earth oxide based materials, ternary oxide based materials such as strontium ruthenium oxide [SRO], etc.) or from nitride-based films (e.g., TaN) that are used as an oxygen barrier between copper and the low-k layer. The wafers may include barrier layers, such as manganese, manganese oxide, etc. Plastic layers, such as poly(3,4-ethylenedioxythiophene)poly (styrenesulfonate) [PEDOT:PSS] may also be used. The layers may be planar or patterned. For example, the layer may be a patterned photoresist film made of hydrogenated carbon, for example CHₓ, wherein x is greater than zero. The preferred substrate is Si, SiO₂ or SiN.

The disclosed processes may deposit the Ge-containing layer directly on the wafer or directly on one or more than one (when patterned layers form the substrate) of the layers on top of the wafer. The substrate may be patterned to include vias or trenches having high aspect ratios. For example, a conformal Ge-containing film, such as Ge, may be deposited using any ALD technique having an aspect ratio ranging from approximately 20:1 to approximately 100:1. Furthermore, one of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates. In many instances though, the preferred substrate utilized may be selected from hydrogenated carbon, TiN, SRO, Ru, and Si type substrates, such as polysilicon or crystalline silicon substrates. For example, a silicon nitride film may be deposited onto a Si layer. In subsequent processing, alternating silicon oxide and silicon nitride layers may be deposited on the silicon nitride layer forming a stack of multiple SiO₂/SiN layers used in 3D NAND gates.

The disclosed Ge-containing film forming compositions may be supplied either in neat form or in a blend with a suitable solvent, such as toluene, ethyl benzene, xylene, mesitylene, decane, dodecane, octane, hexane, pentane, tertiary amines, acetone, tetrahydrofuran, ethanol, ethylmethylketone, 1,4-dioxane, or others. The disclosed compositions may be present in varying concentrations in the solvent. For example, the resulting concentration may range from approximately 0.05M to approximately 2M.

The neat or blended Ge-containing film forming compositions are delivered into a reactor in vapor form by conventional means, such as tubing and/or flow meters. The composition in vapor form may be produced by vaporizing the neat or blended composition through a conventional vaporization step such as direct vaporization, distillation, by bubbling, or by using a sublimator such as the one disclosed in PCT Publication WO2009/087609 to Xu et al. The neat or blended composition may be fed in liquid state to a vaporizer where it is vaporized before it is introduced into the reactor. Alternatively, the neat or blended composition may be vaporized by passing a carrier gas into a container containing the composition or by bubbling of the carrier gas into the composition. The carrier gas may include, but is not limited to, Ar, He, or N₂, and mixtures thereof. Bubbling with a carrier gas may also remove any dissolved oxygen present in the neat or blended composition. The carrier gas and composition are then introduced into the reactor as a vapor.

If necessary, the container may be heated to a temperature that permits the Ge-containing film forming composition to be in its liquid phase and to have a sufficient vapor pressure. The container may be maintained at temperatures in the range of, for example, 0-150° C. Those skilled in the art recognize that the temperature of the container may be adjusted in a known manner to control the amount of Ge-containing film forming composition vaporized.

In addition to the disclosed cyclic Ge(II) silylamido precursor, a co-reactant may also be introduced into the reactor depending on various applications. That is, depending on what specific Ge-containing film to produce, the corresponding co-reactant may be introduced into the reactor.

For manufacturing Ge and O-containing films, the co-reactant may be an oxidizing agent, such as one of O₂, O₃, H₂O, H₂O₂, NO, NO₂, oxygen containing radical and plasma species, such as O. or OH., NO, NO₂; alcohol, silanols, aminoalcohols, carboxylic acids such as formic acid, acetic acid, propionic acid, para-formaldehyde, other oxidizing compounds and mixtures thereof. Preferably, the oxidizing agent is selected from the group consisting of O₂, O₃, H₂O, H₂O₂, NO, NO₂, oxygen containing radicals thereof such as O. or OH., and mixtures thereof. Preferably, when an ALD process is performed, the co-reactant is plasma treated oxygen, ozone, or combinations thereof. When an oxidizing agent is used as the co-reactant, the resulting Ge-containing film will also contain oxygen.

Alternatively, the co-reactant may be a N-containing reducing agent introduced into the reactor to manufacture the Ge and N-containing films, such as one of NH₃, N₂, H₂ or N₂/H₂, amines, diamines, cyanides, di-imines, hydrazines (for example, N₂H₄, MeHNNH₂, MeHNNHMe), organic amines (for example, N(CH₃)H₂, N(C₂H₅)H₂, N(CH₃)₂H, N(C₂H₅)₂H, N(CH₃), N(C₂H₅)₃, (SiMe₃)₂NH), pyrazoline, pyridine, radical and plasma species, and mixtures thereof. Preferably, the N-containing reducing agent is NH, N₂, H₂ or N₂/H₂ or their radical and plasma species, and mixtures thereof. When an N-containing reducing agent is used, the resulting Ge-containing film will also contain nitrogen.

Alternatively, the co-reactant may be a Si-containing reducing agent introduced into the reactor to produce Ge and Si-containing films, such as one of (SiH₃)₃N, SiHₐX₄₋ₐ (X═Cl, Br, I; 0≤a≤4) (for example, SiH₂Cl₂ (DCS), SiH₂I₂ (DIS), SiH₄), Si₂H_{b}X_{c} (X═Cl, Br, I; 0≤b≤6; 0≤c≤6), (for example, Si₂HCl₅, Si₂Cl₆, Si₂H₆), Si₃H_{d}Xₑ (X═Cl, Br, I; 0≤d≤8; 0≤e≤8), (for example, Si₃Cl₈, Si₃H₈), hydridosilanes (for example, Si₄H₁₀, Si₅H₁₀, Si₆H₁₂), chlorosilanes and chloropolysilanes (for example, SiHC₃, SiH₃Cl, Si₂Cl₆, Si₂HCl₅, Si₃Cl₈), alkylsilanes (for example, (CH₃)₂SiH₂, (C₂H₅)₂SiH₂, (CH₃)SiH₃, (C₂H₅)SiH₃), alkylaminosilanes, alkylamino disilanes, alkylaminotrisilanes (for example, Si₃H₇—NR¹R²), silylene compounds and mixtures thereof. The Si-containing reducing agent may be plasma treated. Preferably, the Si-containing reducing agent is SiH₄, Si₂H₆, Si₃H₈, SiH₂Me₂, SiH₂Et₂, N(SiH₃)₃, and mixtures thereof. Preferably, the Si-containing reducing agent is SiHCl₃, Si₂Cl₆, Si₂HCl₅, Si₂H₂Cl₄, cyclo-Si₆H₆Cl₆ and mixtures thereof. When a Si-containing reducing agent is used as the co-reactant, the resulting Ge-containing film will also contain silicon.

Alternatively, the co-reactant may be an additional Ge-containing reactant introduced into the reactor for depositing Ge-containing films. The disclosed cyclic Ge(II) silylamido precursor may be combined with the additional Ge-containing reactant to deposit the Ge-containing films. The additional Ge-containing reactant may be GeCl₄, GeI₄, GeI₂, GeCl₂:L, GeI₂:L (L=dioxane and other neutral adduct). The ratio of the disclosed cyclic Ge(II) silylamido precursor versus the additional Ge-containing reactant may range from 100:1 to 1:100.

Alternatively, the co-reactant may be an additional S/Se/Te-containing reactant introduced into the reactor for depositing Ge and S/Se/Te-containing films. The disclosed cyclic Ge(II) silylamido precursor may be combined with the additional S/Se/Te-containing reactant for depositing the Ge and S/Se/Te-containing films. The additional S/Se/Te-containing reactant may be H₂X, R—X—R, R₃Si—X—SiR₃ (where X═S, Se, Te; R═C₁-C₁₀ alkyl).

Alternatively, the co-reactant may be an additional P/As/Sb-containing reactant introduced into the reactor for depositing Ge and P/As/Sb containing films. The disclosed cyclic Ge(II) silylamido precursor may be combined with the additional P/As/Sb-containing reactant for depositing the Ge and P/As/Sb containing films. The additional P/As/Sb-containing reactant may be H₃X, RH₂X, R₂HX, R₃X (X═P/As/Sb; R=independently a halogen, a C₁-C₁₀ alkyl, a trialkyl silyl group), R₅X (R=halogen).

Alternatively, the co-reactant may be a halide reactant introduced into the reactor for promoting ALD reaction and creating ALD layers. The disclosed cyclic Ge(II) silylamido precursor may be combined with the halide reactant to modify and treat the surface of the substrate for ALD deposition. The halide reactant may be X₂, HX, SOX₂, SOX₄ (X═Cl, Br, I).

The co-reactants listed above may be treated by plasma, in order to decompose the co-reactant into its radical form. N₂ may also be utilized as a reducing agent when treated with plasma. For instance, the plasma may be generated with a power ranging from about 50 W to about 500 W, preferably from about 100 W to about 200 W. The plasma may be generated or present within the reactor itself. Alternatively, the plasma may generally be at a location removed from the reactor, for instance, in a remotely located plasma system. One of skill in the art will recognize methods and apparatus suitable for such plasma enhancement.

When the desired Ge-containing film also contains another element, for example and without limitation, P, Ga, As, B, Ta, Hf, Nb, Mg, Al, Sr, Y, Ba, Ca, As, Sb, Bi, Sn, Pb, Co, lanthanides (such as Er), or combinations thereof, the co-reactants may include another precursor which is selected from, but not limited to, alkyls, such as Ln(RCp)₃ or Co(RCp)₂, amines, such as Nb(Cp)(NtBu)(NMe₂)₃ or any combination thereof.

The disclosed Ge-containing film forming composition and one or more co-reactants may be introduced into the reaction chamber simultaneously (e.g., CVD), sequentially (e.g., ALD), or in other combinations. For example, the Ge-containing film forming composition may be introduced in one pulse and two additional reactants may be introduced together in a separate pulse (e.g., modified ALD). Alternatively, the reaction chamber may already contain the co-reactant prior to introduction of the Ge-containing film forming composition. The co-reactant may be passed through a plasma system localized or remotely from the reaction chamber, and decomposed to radicals. Alternatively, the Ge-containing film forming composition may be introduced to the reaction chamber continuously while other reactants are introduced by pulse (e.g., pulsed-CVD). In each example, a pulse may be followed by a purge or evacuation step to remove excess amounts of the component introduced. In each example, the pulse may last for a time period ranging from about 0.01 s to about 10 s, alternatively from about 0.3 s to about 3 s, alternatively from about 0.5 s to about 2 s. In another alternative, the Ge-containing film forming composition and one or more co-reactants may be simultaneously sprayed from a shower head under which a susceptor holding several wafers is spun (e.g., spatial ALD).

In one non-limiting exemplary ALD type process, the vapor phase of a Ge-containing film forming composition is introduced into the reaction chamber, where at least part of the cyclic Ge(II) silylamido precursor reacts with a suitable substrate, such as Si, SiO₂, Al₂O₃, etc., to form an adsorbed Ge layer. Excess composition may then be removed from the reaction chamber by purging and/or evacuating the reaction chamber. H or NH₃ is introduced into the reaction chamber where it reacts with the adsorbed Ge layer in a self-limiting manner. Any excess H or NH₃ is removed from the reaction chamber by purging and/or evacuating the reaction chamber. If the desired film is a Ge film, this two-step process may provide the desired film thickness or may be repeated until a film having the necessary thickness has been obtained.

Alternatively, if the desired Ge-containing film contains a second element (i.e., GeM, where M is P, Ga, As, B, Ta, Hf, Nb, Mg, Al, Sr, Y, Ba, Ca, As, Sb, Bi, Sn, Pb, Co, lanthanides (such as Er), or combinations thereof), the two-step process above may be followed by introduction of a vapor of a second precursor into the reaction chamber. The second precursor will be selected based on the nature of the GeM film being deposited. After introduction into the reaction chamber, the second precursor is contacted with the substrate. Any excess second precursor is removed from the reaction chamber by purging and/or evacuating the reaction chamber. Once again, H or NH₃ may be introduced into the reaction chamber to react with the second precursor. Excess H or NH₃ is removed from the reaction chamber by purging and/or evacuating the reaction chamber. If a desired film thickness has been achieved, the process may be terminated. However, if a thicker film is desired, the entire four-step process may be repeated. By alternating the provision of the cyclic Ge(II) silylamido precursor, second precursor, and H or NH₃, a film of desired composition and thickness can be deposited.

Additionally, by varying the number of pulses, films having a desired stoichiometric Ge:M ratio may be obtained (M is P, Ga, As, B, Ta, Hf, Nb, Mg, Al, Sr, Y, Ba, Ca, As, Sb, Bi, Sn, Pb, Co, lanthanides (such as Er), or combinations thereof). For example, a GeM film may be obtained by having one pulse of the Ge-containing film forming composition and one pulses of the second precursor, with each pulse being followed by pulses of the oxygen source. However, one of ordinary skill in the art will recognize that the number of pulses required to obtain the desired film may not be identical to the stoichiometric ratio of the resulting film.

In yet another alternative, a Ge-containing film may be deposited by the flowable PECVD method disclosed in U.S. Patent Application Publication No. US2014/0051264 A1 using the disclosed compositions and a radical nitrogen-containing reactant. The radical nitrogen-containing reactant, such as NH₃, is generated in a remote plasma system. The radical reactant and the vapor phase of the disclosed compositions are introduced into the reaction chamber where they react and deposit the initially flowable film on the substrate. Applicants believe that the nitrogen atoms of the amino groups in the disclosed precursors help to further improve the flowability of the deposited film, resulting in films having less voids or pores (i.e., dense films).

The Ge-containing films resulting from the processes discussed above may include Ge or MₓGe, wherein M is an element such as Si, Hf, Zr, Ti, Nb, Ta, and x may be from 0-4, depending on the oxidation state of M. One of ordinary skill in the art will recognize that by judicial selection of the appropriate Ge-containing film forming composition and reactants, the desired film composition may be obtained.

Upon obtaining a desired film thickness, the film may be subject to further processing, such as thermal annealing, furnace-annealing, rapid thermal annealing, UV or e-beam curing, and/or plasma gas exposure. Those skilled in the art recognize the systems and methods utilized to perform these additional processing steps. For example, the Ge-containing film may be exposed to a temperature ranging from approximately 200° C. and approximately 1000° C. for a time ranging from approximately 0.1 second to approximately 7200 seconds under an inert atmosphere, a H-containing atmosphere, a N-containing atmosphere, an O-containing atmosphere, or combinations thereof. Most preferably, the temperature is 600° C. for less than 3600 seconds under an H-containing atmosphere. The resulting film may contain fewer impurities and therefore may have improved performance characteristics. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the Ge-containing film.

### EXAMPLES

The following non-limiting examples are provided to further illustrate embodiments of the invention. However, the examples are not intended to be all inclusive and are not intended to limit the scope of the inventions described herein.

### Comparative Example 1. Synthesis of tBu-Type Compound [tBu-(N—)—SiMe₂-(N—)-tBu]Ge(II)

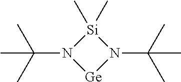

Ligand synthesis: 59.5 g tert-butylamine ((CH₃)₃CNH₂) in 170 mL diethyl ether (CH₃CH₂)₂O, Et₂O) was slowly added to 25 g Me₂SiCl₂ in 50 mL Et₂O at a temperature range from 0° C. to room temperature. The mixture was stirred for ca. 12 hours and filtered. The solvent was removed to give 27.3 g (70% yield) of a crude product ((CH₃)₃CNH)₂Si(CH₃)₂.

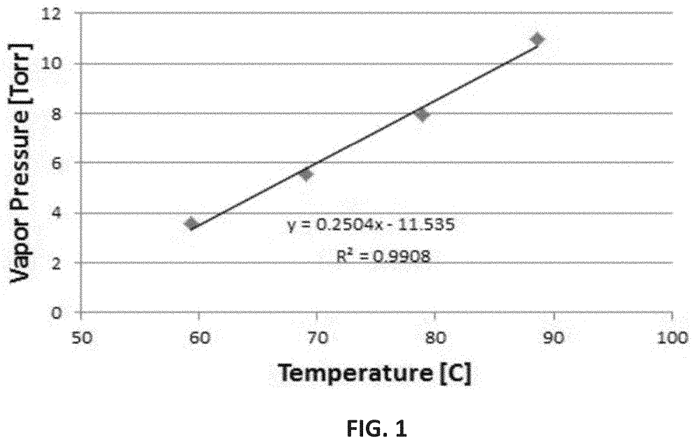

Precursor synthesis: n-BuLi (1.6 M in hexane, 160 mL) was added to 26.0 g of bis(tert-butylamino)dimethylsilane ((CH₃)₃CNH)₂Si(CH₃)₂ in 40 mL of hexane at −30° C. After stirring at room temperature for 1 hour the mixture was heated under reflux for another 1 hour. Obtained solution was added dropwise to the solution of 29.8 g GeCl₂(dioxane) complex in 200 mL Et₂O at −78° C. and the mixture was gradually warmed to room temperature during ca. 12 hours. The volatiles were evaporated, and the residue was dissolved in n-pentane and filtered. After removal of the solvent and distillation 27.5 g of the product [tBu-(N—)—SiMe₂-(N—)-tBu]Ge(II) was obtained as an yellow liquid (78% yield), bp 45° C. at 0.1 Torr. See Z. Naturforsch. 1982, 37b, p 1375-1381. Vapour pressure of the product is 3.5 Torr at 60° C. (FIG. 1). The final product is a yellow liquid.

### Example 1. Synthesis of TMS Substituted Ge(II) Precursor [SiMe₃-(N—)—SiMe₂-(N—)—SiMe₃]Ge(II)

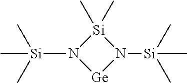

The synthesis route of [SiMe₃-(N—)—SiMe₂-(N—)—SiMe₃]Ge(II) was optimized and summarized as follows, which ensures synthesis safety and reproducibility.

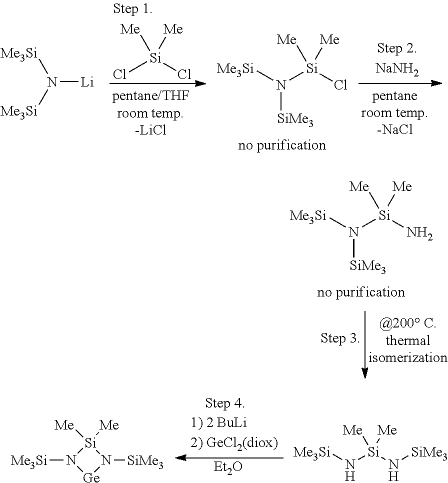

Step 1: Reaction between [Me₃Si]₂NLi (Lithium bis(trimethylsilyl)amide, LiHMDS) and Me₂SiCl₂;
Step 2: Reaction between amino(chloro)silane obtained from Step 1 and NaNH₂;
Step 3: Selective thermal isomerization of the product from Step 2, then distillation; and
Step 4: Synthesis of Ge(II) precursor.

Ligand synthesis: Solution of 30 g dichlorodimethylsilane Me₂SiCl₂ in 30 mL of n-pentane was added to a stirred suspension of 30 g lithium bis(trimethylsilyl)amide in 70 mL of n-pentane. After slow addition of 30 ml THF, the mixture was stirred overnight (less than 24 h). Resulting solution was separated by decantation and remaining solid was washed with n-pentane. After removal of volatiles from combined organic fraction, obtained residue was dissolved in n-pentane and filtered. The solvent was removed in vacuum to give crude amino(chloro)silane ((CH₃)₃Si)₂NSi(CH₃)₂Cl of satisfactory purity as a colorless liquid, which was used on the next step without further purification.

Next step: The obtained silane ((CH₃)₃Si)₂NSi(CH₃)₂Cl was dissolved in 30 mL of n-pentane and added to the stirred suspension of 8.39 g sodium amide NaNH₂ in 70 mL of n-pentane at room temperature. The slurry was stirred overnight and the resulting precipitate was removed by decantation/filtration. The solvent was removed to give the product as a colorless liquid ((CH₃)₃Si)₂NSi(CH₃)₂NH₂ of satisfactory purity. The obtained raw product was heated at 200° C. for 5 hours to give the final product ((CH₃)₃SiNH)₂Si(CH₃)₂ quantitatively as a colorless liquid.

Precursor synthesis: n-BuLi (1.6 M in hexane, 0.506 mol, 315 mL) was added to the solution of crude bis(trimethylsilylamino)dimethylsilane (ca. 0.23 mol) in diethyl ether at −78° C. and stirred at this temperature further for 1 h. After stirring at room temperature for 2 h, the obtained solution of dilithium salt was added dropwise to the solution of 53 g of GeCl₂ (dioxane) complex in 360 mL of Et₂O at −78° C. and stirred at this temperature for the next 1 h. The mixture was allowed to warm to room temperature overnight and then heated at 45° C. for 3 h. The volatiles were removed and the residue was dissolved in n-hexane. The precipitate was removed by filtration. After solvent removal and distillation 35 g (50% yield) of the product was obtained as a red oil.

### Example 2. GC-MS Analyses of [SiMe₃-(N—)—SiMe₂-(N—)—SiMe₃]Ge(II)

Characterization of the final product shown in the Example 1 was done by GC-MS, which indicated a single product with characteristic mass peaks for the product [SiMe₃-(N—)—SiMe₂-(N—)—SiMe₃]Ge(II). A crude mixture aliquot (<1 mg) was diluted with 1 mL toluene and then analyzed by GC-MS using GCMS-QP2010 CI ULTRA” EI mode. GC column, Shimadzu SH-Rts-5MS, 30 m, 0.25 mmID, 0.25 mm df, was kept at 40° C. for 4 minutes then heated in 10° C./min up to 300° C. Fragments around 306 m/z (at 14 min from GC) was detected, which confirmed the composition of the product [SiMe₃-(N—)—SiMe₂-(N—)—SiMe₃]Ge(II) (i.e., C₈H₂₄GeN₂Si₃, mass 306.05 g/mol).

### Example 3. TG of [tBu-(N—)—SiMe₂-(N—)-tBu]Ge(II)

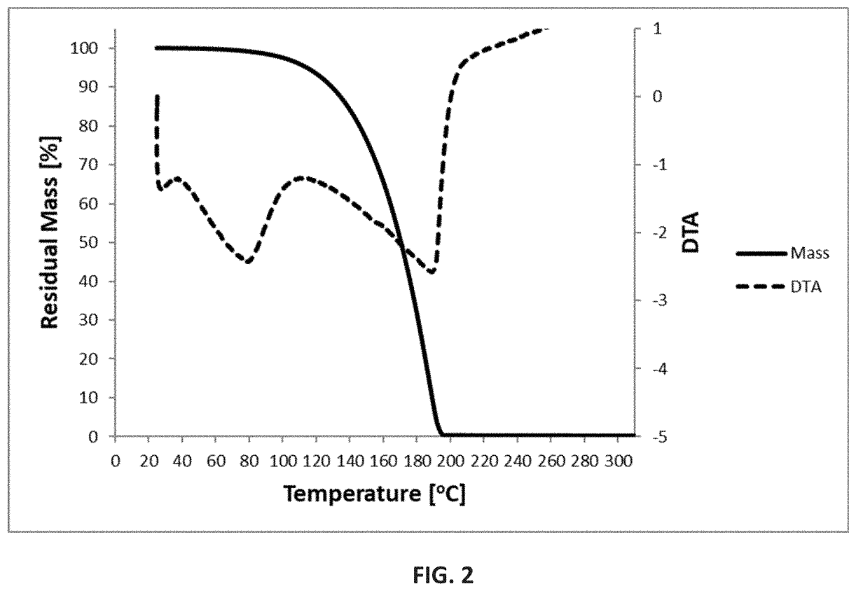

FIG. 2 are TG results of [tBu-(N—)—SiMe₂-(N—)-tBu]Ge(II). The TG results show less than 0.3% residue at 200° C. and no decomposition material was visually found in the post-TG pan. The TG results show [tBu-(N—)—SiMe₂-(N—)-tBu]Ge(II) is thermally stable and has a decent volatility.

### Example 4. DSC of [tBu-(N—)—SiMe₂-(N—)-tBu]Ge(II)

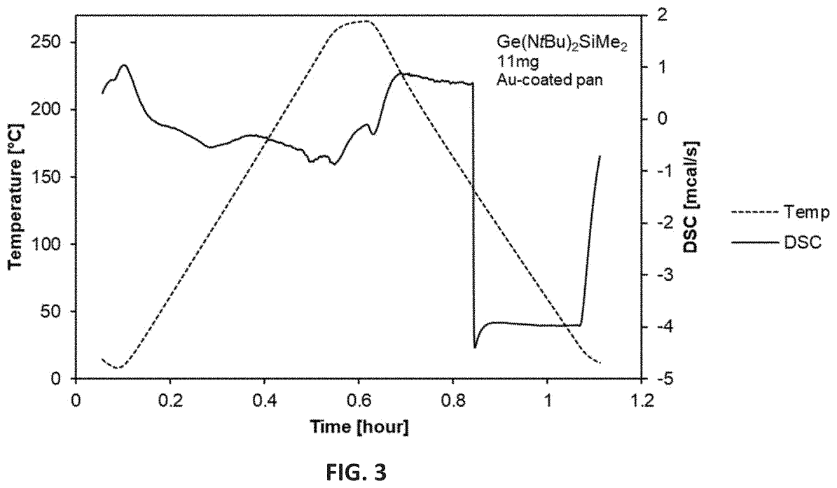

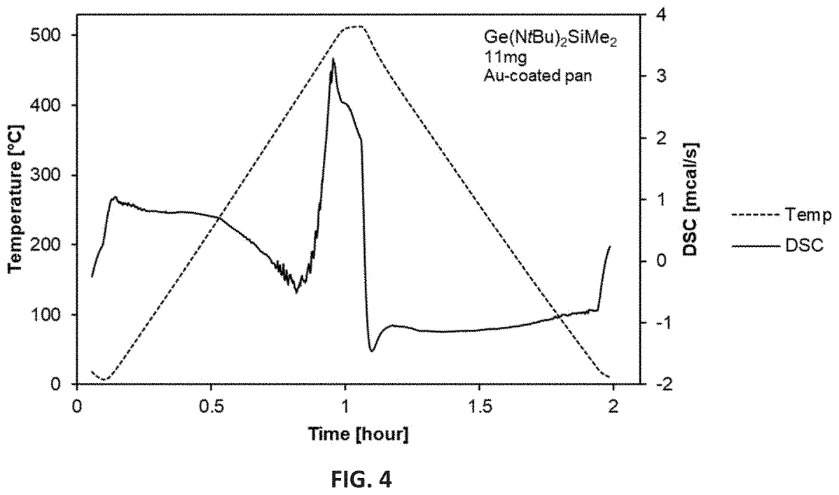

FIG. 3 and FIG. 4 are DSC results of [tBu-(N—)—SiMe₂-(N—)-tBu]Ge(II) from room temperature to 250° C. and from room temperature to 500° C., respectively. FIG. 3 shows that after DSC, Ge precursor recovered without decomposition, which was confirmed by ¹H NMR test (not shown). FIG. 4 shows that after DSC, decomposition occurred and black powder residues were formed to the [tBu-(N—)—SiMe₂-(N—)-tBu]Ge(II) test sample. As such, [tBu-(N—)—SiMe₂-(N—)-tBu]Ge(II) decomposition temperature in the closed DSC pan is between 250° C. and 500° C.

### Example 5. XPS Results of Pyrolysis of [tBu-(N—)—SiMe₂-(N—)-tBu]Ge(II)

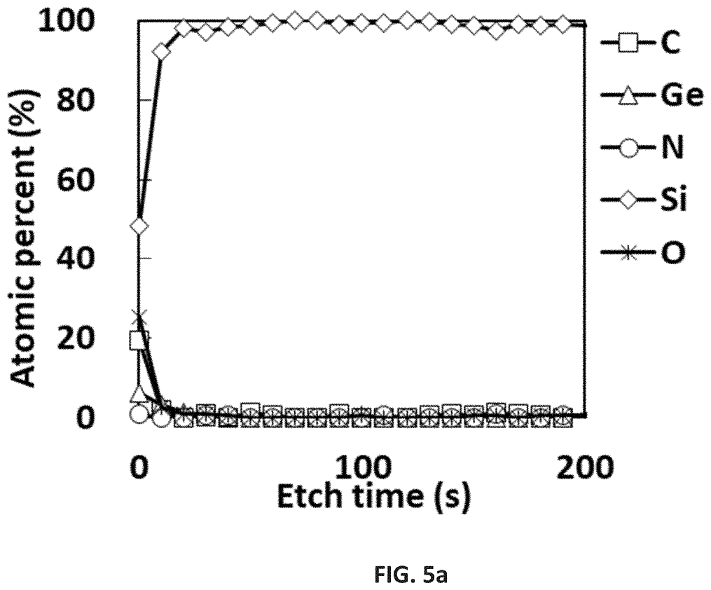

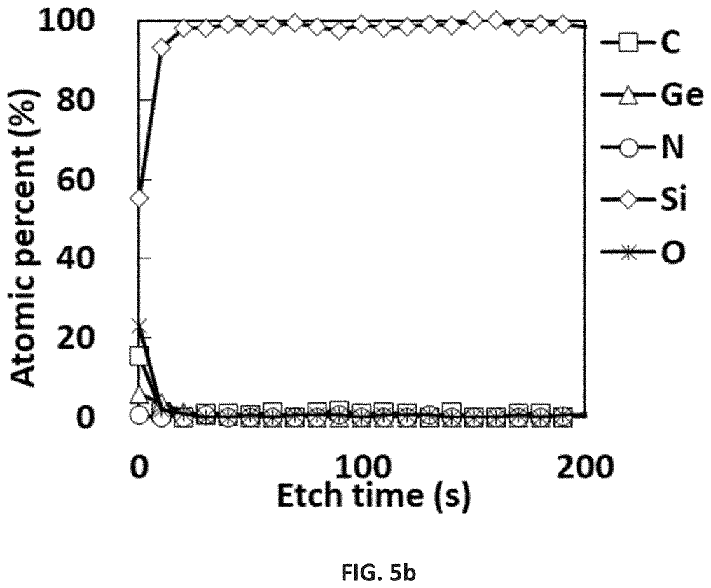

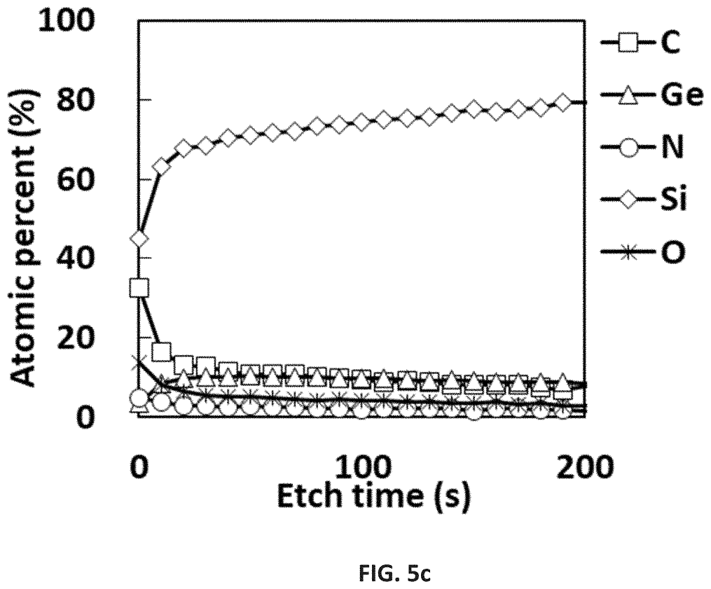

FIG. 5a to FIG. 5c are XPS results of pyrolysis of [tBu-(N—)—SiMe₂-(N—)-tBu]Ge(II) at 375° C., 470° C. and 565° C., respectively, with four coupons and a reference coupon (not shown). No difference observed between coupons and reference at 375° C. and 470° C. However, at 565° C., depositions were observed only on two coupons of the four coupons. The results are summarized in Table 3 below.

TABLE 3

| Temper- | | | Dilution | Pre- | Wafer |
|---|---|---|---|---|---|
| ature of | Process | | N₂ | cursor | position |
| substrate | pressure | Time | flow | flow | in chamber |
| (° C.) | (Torr) | (min) | (sccm) | (sccm) | (cm) |
| 375 | 1 | 40 | 70 | 2 | 5 to 65 |
| 470 | 1 | 40 | 70 | 2 | 5 to 65 |
| 565 | 1 | 40 | 70 | 2 | 5 to 65 |

### Example 6. SEM Results of Deposited Film Using [tBu-(N—)—SiMe₂-(N—)-tBu]Ge(II) at 565° C.

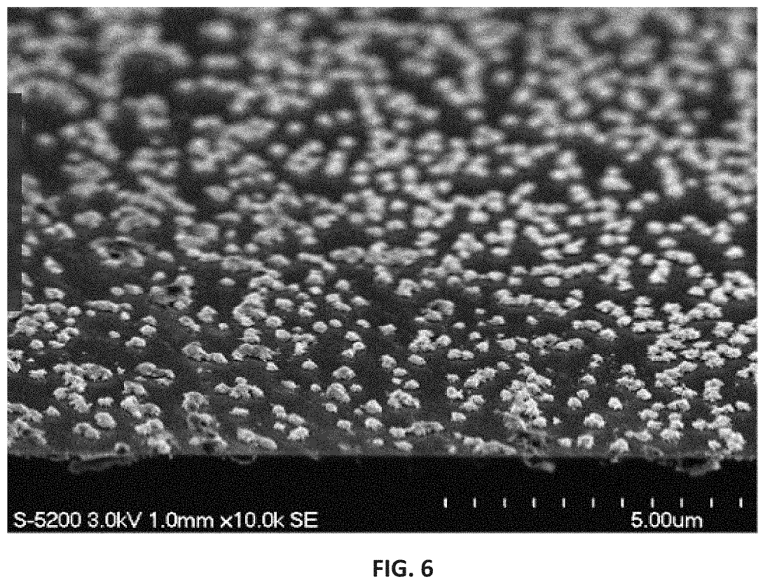

FIG. 6 is SEM results of deposited film using [tBu-(N—)—SiMe₂-(N—)-tBu]Ge(II) at 565° C. As shown, the deposited Ge-containing film using [tBu-(N—)—SiMe₂-(N—)-tBu]Ge(II) is not a uniform film and particles appear on the deposited Ge-containing film at 565° C.

### Example 7. TG and VP of [SiMe₃-(N—)—SiMe₂-(N—)—SiMe₃]Ge(II)

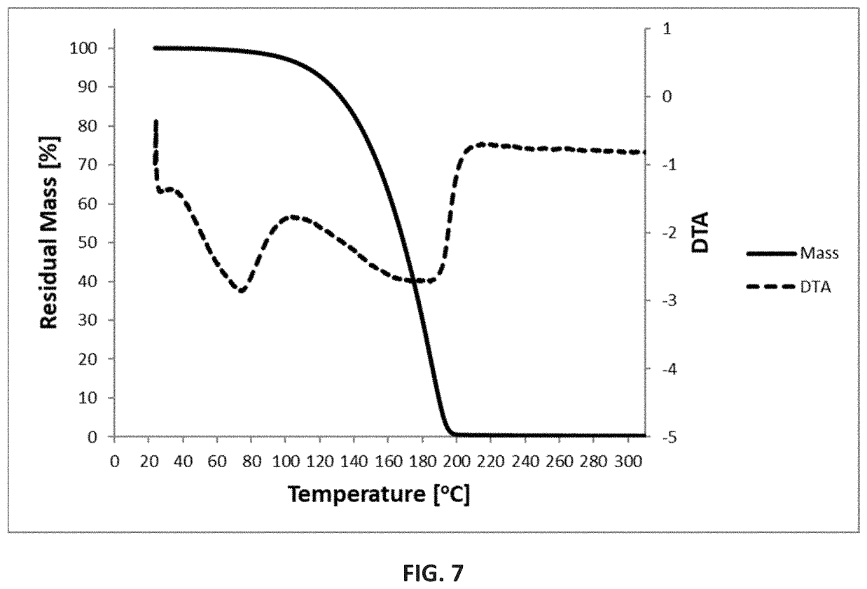

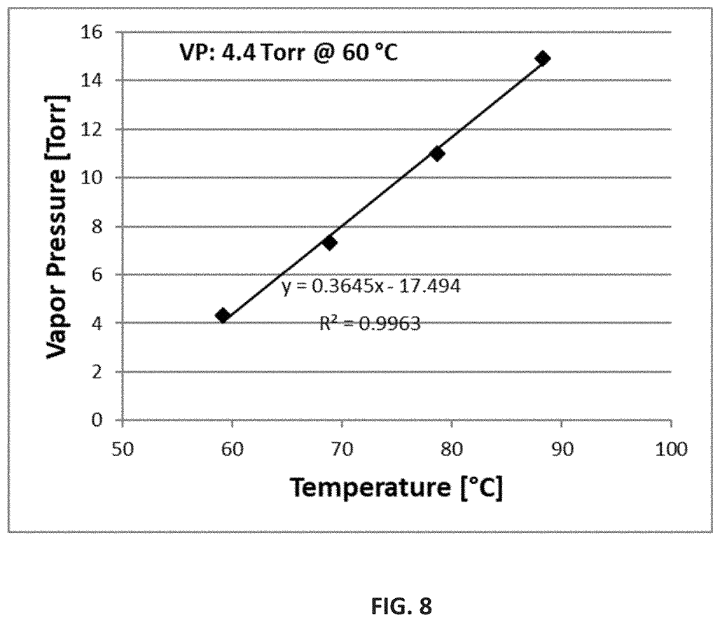

FIG. 7 is TG results of [SiMe₃-(N—)—SiMe₂-(N—)—SiMe₃]Ge(II). The TG results show less than 0.5% residue at 200° C. and no decomposition material was visually found in the post-TG pan. The TG results show [SiMe₃-(N—)—SiMe₂-(N—)—SiMe₃]Ge(II) is thermally stable and has a decent volatility. FIG. 8 is VP results of [SiMe₃-(N—)—SiMe₂-(N—)—SiMe₃]Ge(II). The boiling point of [SiMe₃-(N—)—SiMe₂-(N—)—SiMe₃]Ge(II) is 4.4 Torr at 60° C.

### Example 8. DSC of [SiMe₃-(N—)—SiMe₂-(N—)—SiMe₃]Ge(II)

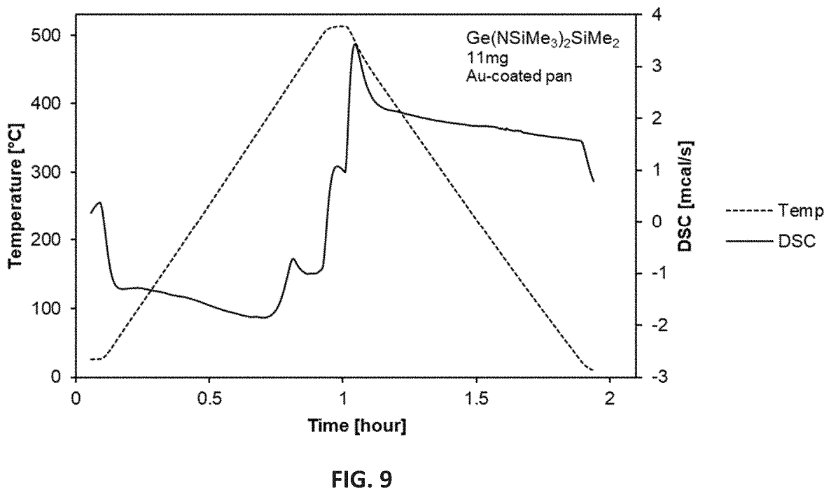

FIG. 9 is DSC results of [SiMe₃-(N—)—SiMe₂-(N—)—SiMe₃]Ge(II) from room temperature to 500° C. Exotherm may be from 380° C. The black material was found in post-DSC pan.

### Example 9. XPS Results of Pyrolysis of [SiMe₃-(N—)—SiMe₂-(N—)—SiMe₃]Ge(II)

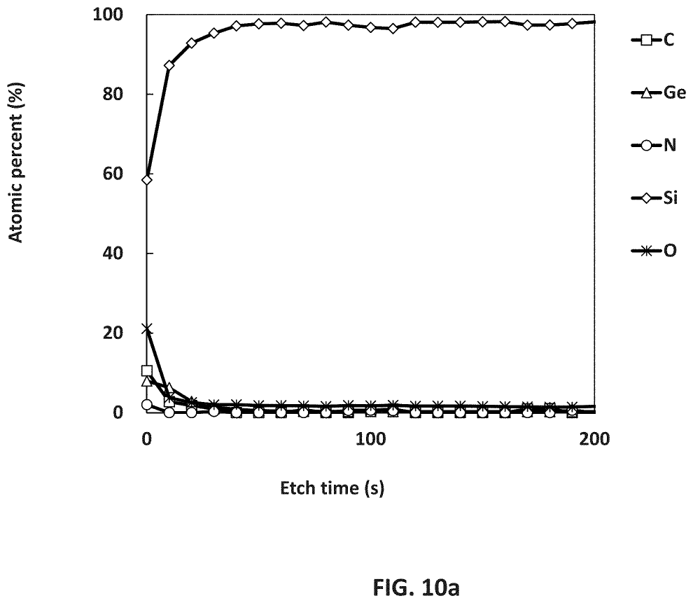

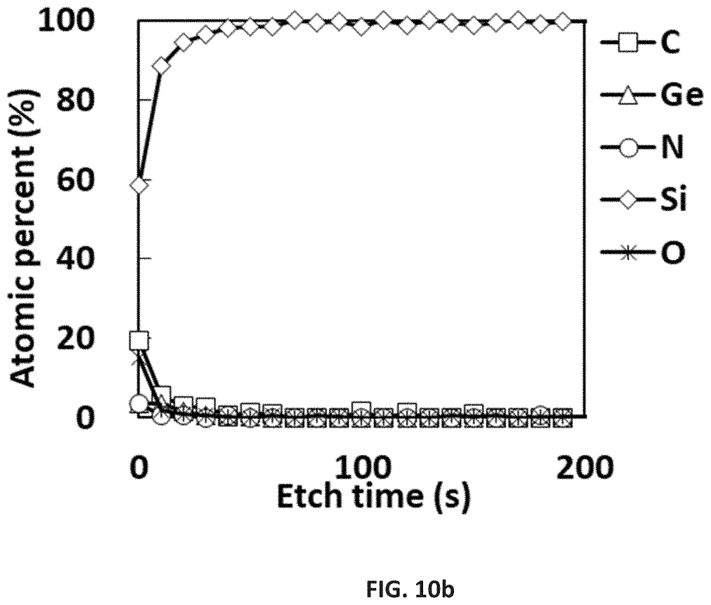

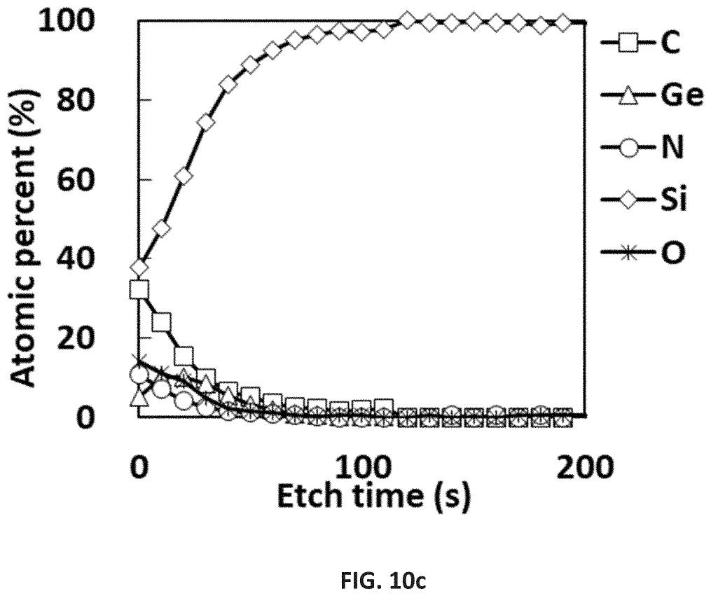

FIG. 10a to FIG. 10c are XPS results of pyrolysis of [SiMe₃-(N—)—SiMe₂-(N—)—SiMe₃]Ge(II) at 565° C., 615° C. and 665° C., respectively, with four coupons and a reference coupon (not shown). No difference observed between coupons and reference at 565° C. and 615° C. However, at 665° C., Ge peak was observed at the surface. The results are summarized in Table 4 below.

TABLE 4

| Temper- | | | Dilution | Pre- | Wafer |
|---|---|---|---|---|---|
| ature of | Process | | N₂ | cursor | position |
| substrate | pressure | Time | flow | flow | in chamber |
| (° C.) | (Torr) | (min) | (sccm) | (sccm) | (cm) |
| 565 | 1 | 40 | 70 | 2 | 5 to 65 |
| 615 | 1 | 40 | 70 | 2 | 5 to 65 |
| 665 | 1 | 40 | 70 | 2 | 5 to 65 |

### Example 10. SEM Results of Deposited Film Using [SiMe₃-(N—)—SiMe₂-(N—)—SiMe₃]Ge(II) at 665° C.

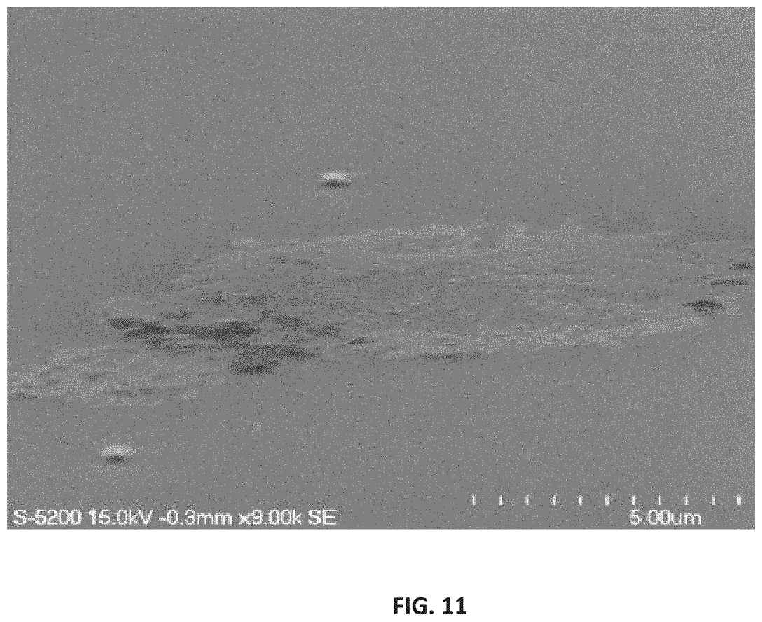

FIG. 11 is SEM results of deposited film using [SiMe₃-(N—)—SiMe₂-(N—)—SiMe₃]Ge(II) at 665° C. As shown, the deposited Ge-containing film using [SiMe₃-(N—)—SiMe₂-(N—)—SiMe₃]Ge(II) is not a uniform film and particles appear on the deposited Ge-containing film at 665° C.

### Example 11. Growth Per Cycle (GPC) Versus Deposition Temperature of ALD of [tBu-(N—)—SiMe2-(N—)-tBu]Ge(II) with Ozone

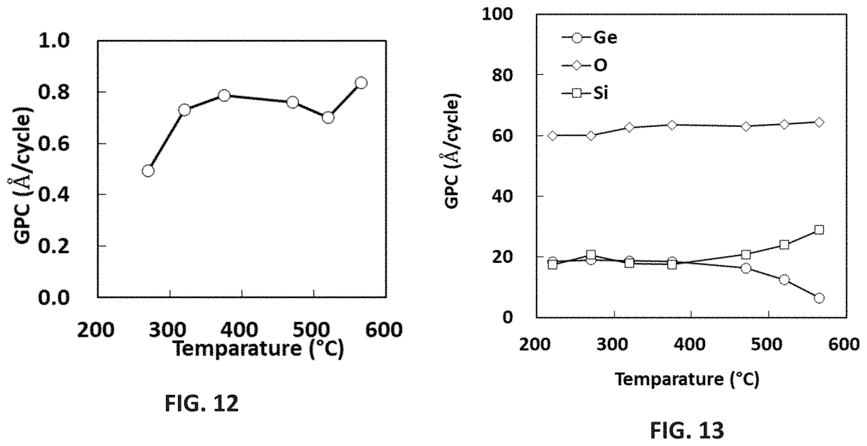

FIG. 12 is the GPC versus ALD temperature form 270° C. to 565° C. using [SiMe₃-(N—)—SiMe₂-(N—)—SiMe₃]Ge(II). The [tBu-(N—)—SiMe2-(N—)-tBu]Ge(II) saturation was observed at 375° C. FIG. 13 is the composition ratio on the ALD GeSi oxide films using [tBu-(N—)—SiMe₂-(N—)-tBu]Ge(II) with ozone at 220° C., 270° C., 320° C., 375° C., 470° C., 520° C. and 565° C. No difference observed at 220° C., 270° C., 320° C. and 275° C. However, from 470° C., Ge concentration was decrease with increasing the deposition temperature.

### Example 12. Optical Transmittance and Reflectance of ALD GeSi Oxide Film Using [tBu-(N—)—SiMe2-(N—)-tBu]Ge(II) with Ozone

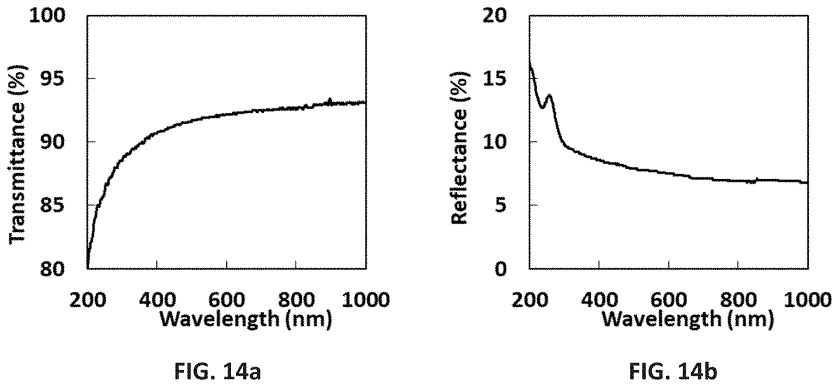

FIG. 14a and FIG. 14b are optical transmittance and reflectance of ALD GeSi oxide film using [tBu-(N—)—SiMe2-(N—)-tBu]Ge(II) at 375° C., respectively.

### Example 13. Growth Per Cycle (GPC) Versus Deposition Temperature of ALD of [SiMe₃-(N—)—SiMe₂-(N—)—SiMe₃]Ge(II) with Ozone

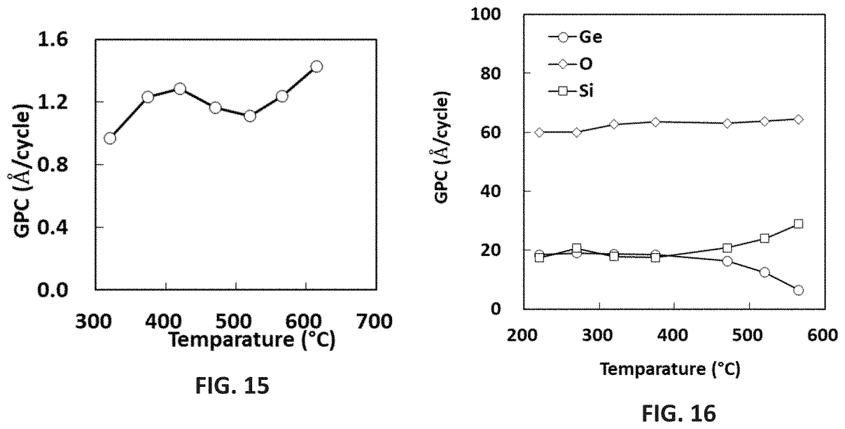

FIG. 15 is the GPC versus ALD temperature form 320° C. to 615° C. using [SiMe₃-(N—)—SiMe₂-(N—)—SiMe₃]Ge(II). The [SiMe₃-(N—)—SiMe₂-(N—)—SiMe₃]Ge(II) saturation was observed at 420° C. FIG. 16 is the composition ratio on the ALD GeSi oxide films using [SiMe₃-(N—)—SiMe₂-(N—)—SiMe₃]Ge(II) with ozone at 320° C., 375° C., 420° C., 470° C., 520° C., 565° C. and 615° C. From 320° C., Ge concentration was decrease with increasing the deposition temperature.

### Example 14. Optical Transmittance and Reflectance of ALD GeSi Oxide Film Using [SiMe₃-(N—)—SiMe₂-(N—)—SiMe₃]Ge(II) with Ozone

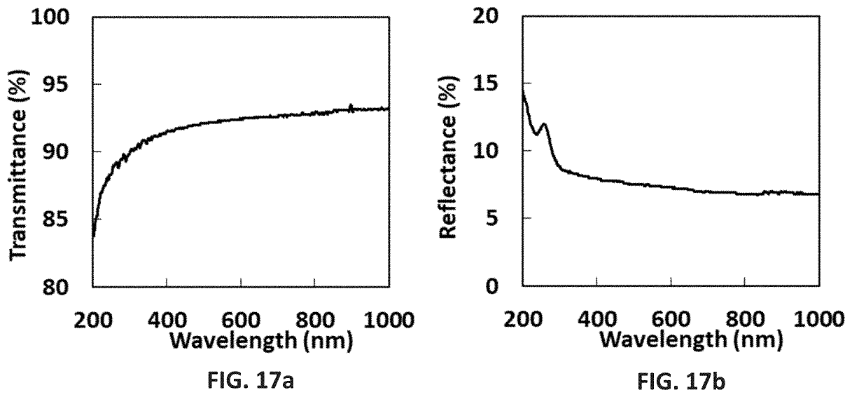

FIG. 17a and FIG. 17b are optical transmittance and reflectance of ALD GeSi oxide film using [SiMe₃-(N—)—SiMe₂-(N—)—SiMe₃]Ge(II) at 375° C., respectively.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

What is claimed is:

1. A method for forming a Ge-containing film on a substrate, the method comprising the steps of:
exposing the substrate to a vapor of a cyclic Ge(II) silylamido precursor, wherein the cyclic Ge(II) silylamido precursor has a general formula:
Ge(II)(—N(R¹)—SiR₂—N(R²)—)
where R is selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group; R¹ and R² each are independently selected from a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, a C₁ to C₁₀ fluorinated alkyl group, or a silyl group SiR′₃ with each R′ being selected from a H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group;
forming a chemisorbed and/or physisorbed film of the cyclic Ge(II) silylamido precursor on the surface of the substrate; and
depositing at least part of the cyclic Ge(II) silylamido precursor onto the substrate to form the Ge-containing film using a vapor deposition method.

2. The method of claim 1, wherein the vapor deposition method is ALD, CVD or a combination thereof.

3. The method of claim 1, further comprising the step of delivering into the reactor a co-reactant.

4. The method of claim 3, wherein the co-reactant is an oxidizing agent selected from O₂, O₃, H₂O, H₂O₂, NO, NO₂, alcohol, silanols, aminoalcohols, carboxylic acids, para-formaldehyde, or mixtures thereof.

5. The method of claim 3, wherein the co-reactant is a nitrogen-containing reducing agent selected from NH₃, N₂, H₂ or N₂/H₂, amines, diamines, cyanides, di-imines, hydrazines, organic amines, pyrazoline, pyridine or mixtures thereof.

6. The method of claim 3, wherein the co-reactant is a silicon-containing reducing agent selected from (SiH₃)₃N, SiHₐX₄₋ₐ (X═Cl, Br, I; 0≤a≤4), Si₂H_{b}X_{c} (X═Cl, Br, I; 0≤b≤6; 0≤c≤6), Si₃H_{d}Xₑ (X═Cl, Br, I; 0≤d≤8; 0≤e≤8), hydridosilanes, chlorosilanes, chloropolysilanes, alkylsilanes, alkylaminosilanes, alkylamino disilanes, alkylaminotrisilanes, silylenes or mixtures thereof.

7. The method of claim 3, wherein the co-reactant is a Ge-containing reactant selected from GeCl₄, GeI₄, GeI₂, GeCl₂:L, GeI₂:L (L=dioxane and other neutral adduct) or mixtures thereof.

8. The method of claim 3, wherein the co-reactant is a compound of S/Se/Te selected from H₂X, R—X—R, R₃Si—X—SiR₃ (where X═S, Se, Te; R═C₁-C₁₀ alkyl) or mixtures thereof.

9. The method of claim 3, wherein the co-reactant is a compound of P/As/Sb selected from H₃X, RH₂X, R₂HX, R₃X (X═P/As/Sb; R=independently a halogen, a C₁-C₁₀ alkyl, a trialkyl silyl group), R₅X (R=halogen) or mixtures thereof.

10. The method of claim 3, wherein the co-reactant is a halide source selected from X₂, HX, SOX₂, SOX₄ (X═Cl, Br, I) or mixtures thereof.

11. The method of claim 1, wherein the cyclic Ge(II) silylamido precursor is [tBu-(N—)—SiMe₂-(N—)-tBu]Ge(II).

12. The method of claim 1, wherein the cyclic Ge(II) silylamido precursor is [SiMe₃-(N—)—SiMe₂-(N—)—SiMe₃]Ge(II).

13. The method of claim 1, wherein the Ge-containing film is a Ge(0) metal film.

14. The method of claim 1, wherein the Ge film is a chalcogenide material.

15. The method of claim 1, wherein the Ge-containing film is a Ge oxide film, a Ge nitrogen film, or a GeSi film.

16. The method of claim 1, wherein the Ge-containing film contains a second element, P, Ga, As, B, Ta, Hf, Nb, Mg, Al, Sr, Y, Ba, Ca, As, Sb, Bi, Sn, Pb, Co, lanthanides (such as Er), or combinations thereof.

17. A composition comprising a cyclic Ge(II) silylamido precursor having a general formula:
Ge(II)(—N(R¹)—SiR₂—N(R²)—)
where R is selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group; R¹ and R² each are independently selected from a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, a C₁ to C₁₀ fluorinated alkyl group, or a silyl group SiR′₃ with each R′ being selected from a H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group.

18. The composition of claim 17, wherein the cyclic Ge(II) silylamido precursor is [SiMe₃-(N—)—SiMe₂-(N—)—SiMe₃]Ge(II).

19. A film forming precursor having a general formula:
Ge(II)(—N(R¹)—SiR₂—N(R²)—)
where R is selected from H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, or a C₁ to C₁₀ fluorinated alkyl group; R¹ and R² each are independently selected from a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C₁₀ heterocyclic group, a C₁ to C₁₀ fluorinated alkyl group, or a silyl group SiR′₃ with each R′ being selected from a H, a C₁ to C₁₀ linear alkyl group, a C₃ to C₁₀ branched alkyl group, a C₃ to C₁₀ cyclic alkyl group, a C₃ to C₁₀ alkenyl group, a C₄ to C₁₀ aryl group, a C₄ to C10 heterocyclic group, or a C₁ to C10 fluorinated alkyl group.

20. The film forming precursor of claim 19, wherein the cyclic Ge(II) silylamido precursor is [SiMe₃-(N—)—SiMe₂-(N—)—SiMe₃]Ge(II).
